(19) United States
(12) Patent Application Publication
(10) Pub. No.: US 2007/0296988 A1
(43) Pub. Date: Dec. 27, 2007

(54) Color conversion definition creating method, profile creating method, color conversion definition creating apparatus, profile creating apparatus, color conversion definition creating program storage medium, and profile creating program storage medium

(75) Inventor: Tetsuya Tsuji, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM Corporation, Minato-ku (JP)

(21) Appl. No.: 11/819,050

(22) Filed: Jun. 25, 2007

(30) Foreign Application Priority Data
Jun. 26, 2006 (JP) 2006-174950

(51) Int. Cl. G03F 3/08

(52) U.S. Cl. 358/1.9; 358/518

(57) ABSTRACT

A color reproduction range excellent in a printing step on an L*a*b* color space is extracted using a B2A1 profile and an A2B1 profile in this order, a dummy RGB gamut for a virtual device obtained by tracing the color reproduction range is created, and, using the dummy RGB gamut, gamut conversion for converting a gamut of a printer as an RGB device into a dummy RGB gamut is performed.

### BACKGROUND OF THE INVENTION

1. Field of the Invention

The present invention relates to a color conversion definition creating method and a color conversion definition creating apparatus for converting a coordinate point in a color reproduction range of a device (e.g., a printer), which mediates an image and image data, in a three-dimensional color space (an RGB color space) dependent on the device and has R (red), G (green), and B (blue) as axes into a coordinate point in a color reproduction range for printing in a four-dimensional color space (a CMYK color space), which has C (cyan), M (magenta), Y (yellow), and K (black) for printing as axes, a storage medium having stored therein a color conversion definition creating program for causing an information processing apparatus such as a computer to operate as the color conversion definition creating apparatus, a profile creating method and a profile creating apparatus for creating a profile for linking different color spaces, and a storage medium having stored therein a profile creating program for causing the information processing apparatus such as a computer to operate as the profile creating apparatus.

2. Description of the Related Art

Conventionally, as an apparatus that applies high-quality color processing for printing to image data representing an image, there is known an apparatus that inputs CMY data representing a combination of respective density values of C, M, and Y (a coordinate point in a CMY color space) and outputs CMYK data representing a combination of respective dot percentages of C, M, Y, and K (a coordinate point in a CMYK color space) (see, for example, Japanese Patent Application Laid-Open No. Hei 9-83824).

This apparatus is an apparatus that inputs CMY data and applies color processing to the CMY data. A technique for the apparatus is basically established to some degree, although various improvements and proposals have been still made for the technique in recent years. There are a substantial number of skilled workers who can perform high-quality color processing (this color processing is referred to as “setup”) by operating such an apparatus.

In recent years, there is increasing necessity for obtaining high-quality CMYK data for printing on the basis of color data other than CMY data according to the spread of a color management technique. As an example, it is sometimes requested to receive RGB data representing a combination of respective colors of R, G, and B (a coordinate point in an RGB color space) and print an image that reproduces colors of a print image outputted and obtained by a certain printer on the basis of the RGB data.

In converting RGB data into CMYK data, it is necessary not only to convert the RGB data into CMYK data, from which calorimetrically identical colors can be obtained, but also to convert the RGB data into CMYK data excellent in printability. One of significant elements determining the printability is a value of K. Thus, in converting the RGB data into the CMYK data from which calorimetrically identical colors can be obtained, it is necessary to set the value of K to a value of K corresponding to a printing company, a printing machine, and the like (conforming to a K plate constraint).

A profile of a format of an LUT (Look-Up-Table) is prepared in order to convert RGB data into CMYK data.

FIG. 1 is a schematic diagram showing an example of a system that converts RGB data into CMYK data using a profile. Here, a background art will be explained with reference to FIG. 1.

RGB data representing an image is inputted to a printer 11. In the printer 11, a print image 11a based on the RGB data inputted is outputted. It is requested to create a print image 12a that reproduces colors same as colors of the print image 11a. In this case, this RGB data is inputted to a color converting device 10. A profile created in advance and used for converting RGB data on an input side (RGB data suitable for the printer 11) into CMYK data for printing is stored in the color converting device 10. In the color converting device 10, color conversion based on the profile is performed to convert the RGB data on the input side into CMYK data for printing. The CMYK data obtained by this conversion is sent to a printing system 12. In the printing system 12, for example, a film master is created on the basis of the CMYK data, a printing plate is created on the basis of the film master, printing is performed, and the print image 12a is created.

The profile used in the color converting device 10 is a link profile obtained by linking printer profiles associating the RGB data and a common color space (e.g., here, L*a*b* color space) and print profiles associating the CMYK data and the common color space (the L*a*b* color space). Since a color reproduction range of the printer 11 is different depending on a type and the like of the printer, the printer profiles are profiles created according to the printer. Since the print profiles are different depending on printing conditions (a printing machine, a type of an ink, etc.) of the printing system 12, the print profiles are profiles created for each of the printing conditions. A standard for creation of the profiles is defined by the ICC. Profiles conforming to the ICC standard are referred to as ICC profiles. As the ICC profiles serving as the print profiles, there are an A2B1 profile for regularly converting CMYK data into L*a*b* data and a B2A profile for inversely converting L*a*b* data into CMYK data. As the B2A profile, there are three types of profiles, namely, a B2A1 profile targeting colorimetric coincidence, a B2A0 profile targeting perceptive coincidence, and a B2A2 profile emphasizing a chroma.

The print profiles need to satisfy printability in the printing conditions, i.e., a K plate constraint and limitation on a total quantity of ink. The K plate constraint typically means an ink quantity (0% to 100%) of K (black) corresponding to a value (0% to 100%) of C (cyan) at the time when C is set as a variable. To satisfy the printability, it is necessary to satisfy the K plate constraint on a gray axis connecting W (white) and K (black). The limitation on a total quantity of ink means that a maximum quantity of ink of one pixel is limited to a value (e.g., 244%) lower than 400% (C=M=Y=K=100%, C+M+Y+K=400%), which is a value without any limitation.

This profile is created by a profile maker. There is a problem in that color production and gray level reproduction at the time when the profile is used depend on ability and the like of the profile maker and are not always satisfactory for users.

In order to solve this problem, Japanese Patent Application Laid-Open No. 2005-268982 proposes a technique for inputting a K plate constraint, defining a virtual RGB device that has a color reproduction range approximate to a color reproduction range of printing on the basis of the K plate constraint inputted, gamut-converting input RGB into dummy RGB depending on this virtual RGB device, and then converting the dummy RGB to CMYK. Consequently, it is possible to obtain a print image that satisfies a K plate constraint designated by users and has an impression highly matching that of the input RGB compared with the print image 11a print-outputted and obtained by the printer 11 (see, FIG. 1) on the basis of the input RGB. For later reference, Japanese Patent Application Laid-Open Nos. 2001-103329 and 2004-266590 are cited.

However, in the case of the method proposed in Japanese Patent Application Laid-Open No. 2005-268982, there is a limit in a degree of freedom of the K plate constraint that can be designated. Thus, the users may have to change a K plate constraint that the users have been used for many years. Even if it is possible to provide color reproduction and gray level representation, with which the users are satisfied, by using the technique of Japanese Patent Application Laid-Open No. 2005-268982, if the K plate constraint required by the users are not reproduced at sufficient accuracy, it is likely that the technique is not accepted by the users.

It is conceivable as a measure to repeat improvements on the basis of the technique disclosed in Japanese Patent Application Laid-Open No. 2005-268982 to make it possible to more freely designate a K plate constraint and freely designate limitation on a total quantity of ink. However, regardless of the fact that the K plate constraint and the limitation on a total quantity of ink are designated in creating the print profiles, if the users need to designate a K plate constraint and limitation on a total quantity of ink again, this unpreferably gives the users an impression that a system lacks consistency.

### SUMMARY OF THE INVENTION

The present invention has been made in view of the above circumstances and provides a profile creating method that can directly incorporate, when a profile of a virtual RGB device having a color reproduction range approximate to a color reproduction range of printing is created, printability such as a K plate constraint and limitation on a total quantity of ink designated in creating a print profile, a color conversion designation creating method that adopts the profile creating method and can adjust color reproduction and gray level representation in an advanced manner, a profile creating apparatus and a color conversion definition creating apparatus that adopt the profile creating method and the color conversion definition creating method, and a storage medium having stored therein a profile creating program and a storage medium having stored therein a color conversion definition creating program for causing an information processing apparatus such as a computer to operate as such a profile creating apparatus and color conversion definition creating apparatus.

The invention provides a profile creating method of creating a virtual profile between an RGB color space dependent on a virtual device, which mediates an image and image data, and a predetermined common color space. The profile creating method includes: a color-reproduction-range calculating step of calculating a printable color preproduction range in the common color space, which is obtained by mapping a color reproduction range adjusted for printing in a CMYK color space for printing to the common color space, using an adaptive conversion profile for converting a coordinate point in the CMYK color space for printing into a coordinate point in the common color space and an inverse conversion profile for converting the coordinate point in the common color space into a coordinate point in the color reproduction range adjusted for printing in the CMYK color space for printing and a virtual-profile creating step of creating a virtual profile by linking the printable color reproduction range calculated in the color-reproduction-range calculating step and the RGB color space.

The color-reproduction-range calculating step may include: an inverse conversion step of converting a coordinate point on the common color space into a coordinate point in the color reproduction range adjusted for printing in the CMYK color space using the inverse conversion profile; and an adaptive conversion step of converting the coordinate point in the color reproduction range adjusted to the printing in the CMYK color space obtained in the inverse conversion step into a coordinate point on the common color space using the adaptive conversion profile.

The color-reproduction-range calculating step may be a step of calculating the printable color reproduction range using an A2B1 tag and a B2A1 tag of an ICC profile as the adaptive conversion profile and the inverse conversion profile, respectively.

As described above, as the print profiles, there are the adaptive conversion profile for regularly converting a CMYK color space to a common color space (e.g., an L*a*b* color space) and the inverse conversion profile for inversely converting the common color space (e.g., the L*a*b* color space) into the CMYK color space. By using the adaptive conversion profile and the inverse conversion profile, it is possible to extract a color reproduction range for printing that satisfies printability such as a K plate constraint and limitation on a total quantity of ink (a printable color reproduction range).

The profile creating method according to the invention links the printable color reproduction range extracted in this way and the RGB color space. Consequently, it is possible to create a virtual profile incorporating a color reproduction range having printability such as a K plate constraint.

It is preferable that, in the profile creating method according to the invention, the virtual-profile creating step includes: a vertex-and-ridge-line detecting step of detecting respective vertices of W, R, G, B, C, M, Y, and K of the printable color reproduction range in the common color space calculated in the color-reproduction-range calculating step and twelve ridge lines connecting R and M, M and B, B and C, C and G, G and Y, Y and R, W and C, W and M, W and Y, K and R, K and G, and K and B and associating these vertices and the ridge lines with vertices and ridge lines corresponding thereto, respectively, in the RGB color space; a ridge-line-profile creating step of creating a ridge line profile concerning the respective ridge lines associating a coordinate point in the RGB color space and a coordinate point in the common color space such that, when plural points are set at equal intervals on the respective ridge lines on the RGB color space and the plural points are mapped onto the common color space, the plural points mapped onto the common color space are arranged at equal intervals on the respective ridge lines on the common color space; a gray-axis-profile creating step of creating a gray axis profile concerning a gray axis associating a coordinate point in the RGB color space and a coordinate point in the common color space such that, when plural points are set at equal intervals on the gray axis connecting the vertex of W and the vertex of K on the RGB color space and the plural points are mapped onto the common color space, the plural points mapped onto the common color space are arranged at equal intervals on the gray axis connecting the vertex of W and the vertex of K on the common color space; and an interpolation operation step of creating a virtual profile by associating a coordinate point in the RGB color space and a coordinate point in the common color space over the entire RGB color space according to an interpolation operation with the ridge line profile created in the ridge-line-profile creating step and the gray-axis-profile created in the gray-axis-profile creating step set as boundary conditions.

As described above, the ridge-line-profile creating step and the gray-axis-profile-creating step are provided, coordinates on the ridge lines in the common color space with respect to coordinates on the ridge lines in the RGB color space are rearranged such that the plural points on the ridge lines and the plural points on the gray axis are arranged at equal intervals in both the RGB color space and the common color space (here, an equal interval property in the above meaning is referred to as “RGB value linear”), coordinates on the gray axis are determined to be RGB value linear, and then profiles of the surface other than the ridge lines and the inside other than the gray axis of the color reproduction range of the virtual device are calculated by the interpolation operation. Consequently, it is possible to perform gamut conversion without gray level distortion and improve aptitudes for color reproduction and gray level reproduction, with which users are satisfied.

In this case, it is also possible that, in the vertex-and-ridge-line detecting step, a locus of a color of a maximum chroma in a two-dimensional color reproduction range obtained by projecting the printable color reproduction range on one or more planes is detected and ridge lines connecting R, M, B, C, G, Y, and R in order are detected on the basis of the locus. It is also possible that, in the vertex-and-ridge-line detecting step, by detecting angles in respective hue angle ranges set for R, M, B, C, G, and Y, respectively, of the ridge lines connecting R, M, B, C, G, Y, and R in order detected on the printable color reproduction range, the angles in the respective hue ranges are associated with the respective vertices of R, M, B, C, G, and Y. Moreover, it is also possible that, in the vertex-and-ridge-line detecting step, respective outermost edges connecting respective vertices of R, G, and B and a vertex of K of respective two-dimensional color reproduction ranges obtained by projecting the printable color reproduction range on respective planes including the gray axis (an L* axis or a line connecting the vertex of W and the vertex of K at the time when the L*a*b color space is adopted as the common color space) and the respective vertices of R, G, and B are set as respective ridge lines connecting the respective vertices of R, G, and B and the vertex of K in the printable color reproduction range, and respective outermost edges connecting a vertex of W and respective vertices of C, M, and Y of respective two-dimensional color reproduction ranges obtained by projecting the printable color reproduction range on the respective planes including the gray axis and the respective vertices of C, M, and Y are set as respective ridge lines connecting the vertex of W and the respective vertices of C, M, and Y in the printable color reproduction range.

It is preferable that, in the vertex-and-ridge-line detecting step, noise removal processing is applied to a ridge line once detected to detect a ridge line with noise reduced.

As a noise-removal processing method in the vertex-and-ridge-line detecting step, for example, it is possible to adopt a noise-removal processing method of calculating a chroma ratio of each point on a ridge line once detected to a point adjacent thereto and, when the chroma ratio is equal to or lower than a threshold, removing a point where the chroma is low as noise. Alternatively, instead of this noise-removal processing method or together with this noise-removal processing method, a noise-removal processing method of calculating a difference vector between each point on a ridge line detected once and a point adjacent thereto and, when signs of components in a lightness direction of the difference vector continuously take maximum and minimum, removing these two points of extreme values as noise may be adopted.

The invention provides a color conversion definition creating method of creating a color conversion definition for converting a coordinate point in a color reproduction range of a first device, which mediates an image and image data, in a first RGB color space dependent on the first device into a coordinate point in a color reproduction range for printing in a CMYK color space for printing. The color conversion definition creating method includes: a profile creating step of creating a virtual profile between a second RGB color space and a predetermined common color space, the second RGB color space having a color reproduction range obtained by tracing the color reproduction range for printing and depending on a virtual second device which mediates an image and image data; a first link-profile creating step of creating a first link profile for converting a coordinate point in a color reproduction range of the second device in the second RGB color space into a coordinate point in the color reproduction range for printing in the CMYK color space; and a second link-profile creating step of creating a second link profile for converting a coordinate point in the color reproduction range of the first device in the first RGB color space into a coordinate point in the color reproduction range of the second device in the second RGB color space using a device profile of the first device and the virtual profile created in the profile creating step. The profile creating step includes: a color-reproduction-range calculating step of calculating a printable color reproduction range in the common color space, which is obtained by mapping a color reproduction range adjusted for printing in the CMYK color space for printing to the common color space, using an adaptive conversion profile for converting a coordinate point in the CMYK color space for printing into a coordinate point in the common color space and an inverse conversion profile for converting a coordinate point in the common color space into a coordinate point in the color reproduction range adjusted for printing in the CMYK color space for printing; and a virtual-profile creating step of creating a virtual profile by linking the printable color reproduction range calculated in the color-reproduction-range calculating step and the second RGB color space.

In the color conversion definition creating method according to the invention, since the profile creating method according to the invention is adopted, a virtual profile directly incorporating a K plate constraint, limitation on a total quantity of ink, and the like actually used is created and the gamut conversion is performed from the first RGB color space to the second RGB color space, which is a color space of a virtual device, such that color reproduction and gray level reproduction, with which users can be satisfied, are obtained. Thus, it is possible to improve color reproduction and gray level reproduction while surely satisfying printability such as a K plate constraint.

The profile creating step in the color conversion definition creating method according to the invention includes all the modes of the profile creating method according to the invention.

The invention provides a profile creating apparatus that creates a virtual profile between an RGB color space dependent on a virtual device, which mediates an image and image data, and a predetermined common color space. The profile creating apparatus includes: a color-reproduction-range calculating section that calculates a printable color preproduction range in the common color space, which is obtained by mapping a color reproduction range adjusted for printing in a CMYK color space for printing to the common color space, using an adaptive conversion profile for converting a coordinate point in the CMYK color space for printing into a coordinate point in the common color space and an inverse conversion profile for converting a coordinate point in the common color space into a coordinate point in the color reproduction range adjusted for printing in the CMYK color space for printing; and a virtual-profile creating section that creates a virtual profile by linking the printable color reproduction range calculated by the color-reproduction-range calculating section and the RGB color space.

The profile creating apparatus according to the invention includes all modes for realizing the various modes of the profile creating method according to the invention.

The invention provides a color conversion definition creating apparatus that creates a color conversion definition for converting a coordinate point in a color reproduction range of a first device, which mediates an image and image data, in a first RGB color space dependent on the first device into a coordinate point in a color reproduction range for printing in a CMYK color space for printing. The color conversion definition creating apparatus includes: a profile creating section that creates a virtual profile between a second RGB color space and a predetermined common color space, the second RGB color space having a color reproduction range obtained by tracing the color reproduction range for printing and depending on a virtual second device which mediates an image and image data; a first link-profile creating section that creates a first link profile for converting a coordinate point in a color reproduction range of the second device in the second RGB color space into a coordinate point in the color reproduction range for printing in the CMYK color space; and a second link-profile creating section that creates a second link profile for converting a coordinate point in the color reproduction range of the first device in the first RGB color space into a coordinate point in the color reproduction range of the second device in the second RGB color space using a device profile of the first device and the virtual profile created by the profile creating section. The profile creating section includes: a color-reproduction-range calculating section that calculates a printable color reproduction range in a common color space, which is obtained by mapping a color reproduction range adjusted for printing in the CMYK color space for printing to the common color space, using an adaptive conversion profile for converting a coordinate point in the CMYK color space for printing into a coordinate point in the common color space and an inverse conversion profile for converting a coordinate point in the common color space into a coordinate point in the color reproduction range adjusted for printing in the CMYK color space for printing; and a virtual-profile creating section that creates a virtual device profile by linking the printable color reproduction range calculated by the color-reproduction-range calculating section and the second RGB color space.

The profile creating section in the color conversion definition creating apparatus according to the invention includes all modes for realizing the various modes of the profile creating method according to the invention.

The invention provides a storage medium having stored therein a profile creating program that is executed in an information processing apparatus, which executes a program, and causes the information processing apparatus to operate as a profile creating apparatus that creates a virtual profile between an RGB color space dependent on a virtual device, which mediates an image and image data, and a predetermined common color space. The profile creating program causes the information processing apparatus to operate as a profile creating apparatus including: a color-reproduction-range calculating section that calculates a printable color preproduction range in the common color space, which is obtained by mapping a color reproduction range adjusted for printing in a CMYK color space for printing to the common color space, using an adaptive conversion profile for converting a coordinate point in the CMYK color space for printing into a coordinate point in the common color space and an inverse conversion profile for converting a coordinate point in the common color space into a coordinate point in the color reproduction range adjusted for printing; and a virtual-profile creating section that creates a virtual profile by linking the printable color reproduction range calculated by the color-reproduction-range calculating section and the RGB color space.

The profile creating program according to the invention includes all modes for realizing the various modes of the profile creating method and the profile creating apparatus according to the invention.

The invention provides a storage medium having stored therein a color conversion definition creating program that is executed in an information processing apparatus, which executes a program, and causes the information processing apparatus to operate as a color conversion definition creating apparatus that creates a color conversion definition for converting a coordinate point in a color reproduction range of a first device, which mediates an image and image data, in a first RGB color space dependent on the first device into a coordinate point in a color reproduction range for printing in a CMYK color space for printing. The color conversion definition creating program causes the information processing apparatus to operate as a color conversion definition creating apparatus including: a profile creating section that creates a virtual profile between a second RGB color space and a predetermined common color space, the second RGB color space having a color reproduction range obtained by tracing the color reproduction range for printing and depending on a virtual second device which mediates an image and image data; a first link-profile creating section that creates a first link profile for converting a coordinate point in a color reproduction range of the second device in the second RGB color space into a coordinate point in the color reproduction range for printing in the CMYK color space; and a second link-profile creating section that creates a second link profile for converting a coordinate point in the color reproduction range of the first device in the first RGB color space into a coordinate point in the color reproduction range of the second device in the second RGB color space using a device profile of the first device and the virtual profile created by the profile creating section. The profile creating section includes: a color-reproduction-range calculating section that calculates a printable color reproduction range in a common color space, which is obtained by mapping a color reproduction range adjusted for printing in the CMYK color space for printing to the common color space, using an adaptive conversion profile for converting a coordinate point in the CMYK color space for printing into a coordinate point in the common color space and an inverse conversion profile for converting a coordinate point in the common color space into a coordinate point in the color reproduction range adjusted for printing in the CMYK color space for printing; and a virtual-profile creating section that creates a virtual device profile by linking the printable color reproduction range calculated by the color-reproduction-range calculating section and the second RGB color space.

The color conversion definition creating program according to the invention includes all modes for realizing the various modes of the color conversion definition creating method and the color conversion definition creating apparatus according to the invention.

According to the invention, in creating a profile of a virtual RGB device having a color reproduction range approximate to a color reproduction range for printing, it is possible to create a profile to which printability such as a K plate constraint and limitation on a total quantity of ink are directly applied and it is possible to improve color reproduction and gray level reproduction while keeping the printability high.

### BRIEF DESCRIPTION OF THE DRAWINGS

Preferred embodiments of the present invention will be described in detail based on the following figures, wherein:

FIG. 1 is a schematic diagram showing an example of a system that converts RGB data into CMYK data using a profile;

FIG. 2 is a diagram showing an example of a system employing a color conversion definition created according to the invention;

FIG. 3 is an external perspective view of a personal computer forming an embodiment of a color conversion definition creating apparatus according to the invention;

FIG. 4 is a hardware diagram of the personal computer;

FIG. 5 is a flowchart showing an embodiment of a color conversion definition creating method according to the invention;

FIG. 6 is a flowchart showing a detailed flow of a profile creating step in the color conversion definition creating method shown in FIG. 5;

FIG. 7 is a diagram showing a detailed flow of a color reproduction range calculation process;

FIG. 8 is a diagram showing a detailed flow of a virtual profile creation step;

FIG. 9 is a schematic diagram of an embodiment of a color conversion definition creating program according to the invention;

FIG. 10 is a schematic diagram of a profile creating section, which is one program component in the color conversion definition creating program shown in FIG. 9;

FIG. 11 is a functional diagram of an embodiment of a color conversion definition creating apparatus according to the invention;

FIG. 12 is a functional diagram of a profile creating section of the color conversion definition creating apparatus shown in FIG. 11;

FIG. 13 is a conceptual diagram of a printer profile;

FIG. 14 is a conceptual diagram of an adaptive conversion profile (an A2B1 profile) among print profiles;

FIG. 15 is a conceptual diagram of an inverse conversion profile (a B2A1 profile) among the print profiles;

FIG. 16 is a conceptual diagram of a virtual profile;

FIG. 17 is a conceptual diagram of a link profile;

FIG. 18 is a diagram showing a color reproduction range (dots) represented by the A2B1 profile and a color reproduction range (mesh) represented by the B2A1 profile in an overlapped state;

FIG. 19 is a diagram showing the color reproduction range (dots) represented by the A2B1 profile and the color reproduction range (mesh) represented by the B2A1 profile in an overlapped state;

FIG. 20 is a diagram showing the color reproduction range (dots) represented by the A2B1 profile and the color reproduction range (mesh) represented by the B2A1 profile in an overlapped state;

FIG. 21 is a diagram showing the color reproduction range (dots) represented by the A2B1 profile and the color reproduction range (mesh) represented by the B2A1 profile in an overlapped state;

FIG. 22 is a diagram showing a two-dimensional color reproduction range obtained by projecting a color reproduction range different from the color reproduction range shown in FIGS. 18 to 21 on an a*-b* plane;

FIG. 23 is a diagram showing a two-dimensional color reproduction range obtained by rotating a three-dimensional color reproduction range on an L*a*b* color space, which is the same as the color reproduction range shown in FIG. 22, −20° around an a* axis and then projecting the color reproduction range on the a*-b* plane;

FIG. 24 is a diagram showing ridge lines connecting R-M-B-C-G-Y-R in order calculated from a locus of a color with a maximum chroma of a color reproduction range projected on a plane;

FIG. 25 is a diagram showing the ridge lines connecting R-M-B-C-G-Y-R in order calculated from the locus of the color with the maximum chroma of the color reproduction range projected on the plane;

FIG. 26 is a diagram showing the ridge lines connecting R-M-B-C-G-Y-R in order calculated from the locus of the color with the maximum chroma of the color reproduction range projected on the plane;

FIG. 27 is a diagram showing an example of a color reproduction range that is projected on the a*-b* plane and in which noise removal according to comparison of chromas is effective;

FIG. 28 is a diagram obtained by extracting color points of a maximum chroma at each predetermined angle (here, 5 degrees) from the color reproduction range shown in FIG. 27 and plotting the color points;

FIG. 29 is a diagram showing a locus of a color with a maximum chroma after a filtering operation for performing noise removal according to a chroma ratio is performed once;

FIG. 30 is a diagram showing a locus of the color with the maximum chroma after the filtering operation for performing noise removal according to a chroma ratio is performed twice;

FIG. 31 is a diagram showing a locus of color points remaining after three kinds of filtering processing;

FIG. 32 is a diagram showing a locus of color points remaining after the three kinds of filtering processing;

FIG. 33 is a diagram showing a locus of color points remaining after the three kinds of filtering processing;

FIG. 34 is a schematic diagram showing one of two kinds of methods of detecting a saturated color;

FIG. 35 is an explanatory diagram of a method of detecting a ridge line connecting R and K;

FIG. 36 is a diagram showing six ridge lines connecting R, G, and B and K, respectively, and connecting C, M, and Y and W, respectively;

FIG. 37 is a schematic diagram showing noise reduction processing for a ridge line connecting B and K;

FIG. 38 is a diagram showing a state in which colors are supplemented to increase the number of color points on respective ridges on the L*a*b* color space to eighteen;

FIGS. 39A and 39B are explanatory diagrams of equal interval processing employing 1DLUT for inputting an accumulated color difference and outputting an L* value;

FIGS. 40A and 40B are conceptual diagrams of lattice points on a ridge line before and after the equal interval processing:

FIG. 41 is a diagram showing a color reproduction range before the equal interval processing;

FIG. 42 is a diagram showing a color reproduction range after the equal interval processing;

FIG. 43 is a diagram showing a table representing a gray axis profile;

FIG. 44 is a diagram showing a profile associating dummy RGB and L*a*b* before interpolation operation processing (only a ridge line and a gray axis are associated);

FIG. 45 is a profile (a dummy RGB gamut) associating dummy RGB and L*a*b* after the interpolation operation processing;

FIG. 46 is a diagram showing a dummy RGB gamut (mesh) and (dots of) a printable color reproduction range (B2A1 gamut) in an overlapped state;

FIG. 47 is a diagram showing the dummy RGB gamut (mesh) and (dots of) the printable color reproduction range (B2A1 gamut) in an overlapped state;

FIG. 48 is a diagram showing the dummy RGB gamut (mesh) and (dots of) the printable color reproduction range (B2A1 gamut) in an overlapped state;

FIG. 49 is a diagram showing the dummy RGB gamut (mesh) and (dots of) the printable color reproduction range (B2A1 gamut) in an overlapped state;

FIG. 50 is a conceptual diagram of a method of calculating a link profile;

FIGS. 51a to 51C are schematic diagrams of color reproduction ranges of a printer shown in FIG. 2 and a virtual printer;

FIG. 52 is a flowchart showing a first color conversion definition creation process;

FIG. 53 is a diagram showing a structure of a first color-conversion-definition creating section in a color conversion definition creating program;

FIG. 54 is a functional block diagram of a second link-profile creating section in a color conversion definition creating apparatus;

FIGS. 55A to 55D are explanatory diagrams of a second step (step b21) in a second coordinate conversion step;

FIG. 56 is an explanatory diagram of a first example of coordinate conversion in a first step;

FIG. 57 is a flowchart of the first example;

FIG. 58 is a diagram showing a first modification of the coordinate conversion explained with reference to FIGS. 56 and 57;

FIG. 59 is an explanatory diagram of a second example of the coordinate conversion in the first step;

FIG. 60 is a flowchart of a second example;

FIG. 61 is a diagram showing a modification of the second example of the coordinate conversion;

FIG. 62 is a diagram for explaining an effect of mapping performed by combining “compression” explained with reference to FIGS. 56 and 57 and “expansion” explained with reference to FIGS. 59 and 60;

FIG. 63 is an explanatory diagram of a third example of the coordinate conversion in the first step;

FIG. 64 is a flowchart of a third example;

FIG. 65 is a diagram showing a modification of the third example of the coordinate conversion;

FIG. 66 is an explanatory diagram of a fourth example of the coordinate conversion in the first step;

FIG. 67 is a flowchart of a fourth example;

FIG. 68 is a diagram showing a modification of the fourth example of the coordinate conversion; and

FIG. 69 is a conceptual diagram showing a color conversion definition including a first color conversion definition and a second color conversion definition.

### DETAILED DESCRIPTION OF THE PREFERRED EMBODIMENTS

Embodiments of the present invention will be hereinafter explained.

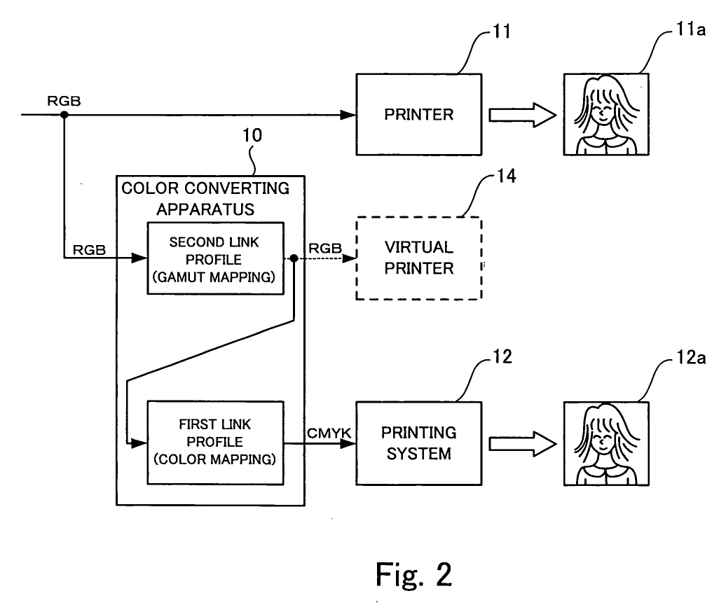

FIG. 2 is a diagram showing an example of a system employing a color conversion definition created according to the invention. First, it will be explained with reference to FIG. 2 where the invention is placed in the technical field.

RGB data representing an image is inputted to a printer 11. In the printer 11, a print image 11a based on the RGB data inputted is outputted. It is requested to create a print image reproducing colors same as colors of the print image 11a. In this case, this RGB data is inputted to a color converting apparatus 10. Details of this color converting apparatus will be described later. The color converting apparatus 10 has stored therein a second link profile that is created in advance according to an embodiment of the invention described later and used for gamut mapping for converting RGB data on an input side (RGB data suitable for the printer 11) into RGB data suitable for a virtual printer 14 and a first link profile for color matching for converting the RGB data, which is converted using the second link profile, into CMYK data for printing. The color converting apparatus 10 performs color conversion based on the second link profile (gamut mapping) and performs color conversion based on the first link profile (color matching) to convert the RGB data on the input side into the CMYK data for printing. For convenience of explanation, the color conversion based on the second link profile (gamut mapping) and the color conversion based on the first link profile (color matching) are separately explained. However, in actually converting the RGB data on the input side to the CMYK data for printing, in order to perform color conversion at high speed, one color conversion definition is created by combining the second link profile and the first link profile and the RGB data on the input side is converted into the CMYK data for printing on the basis of one color conversion definition combined.

The CMYK data generated in this way is sent to a printing system 12. In the printing system 12, for example, a film master is created on the basis of the CMYK data, a printing plate is created on the basis of the film master, printing is performed, and a print image 12a is created.

If the input RGB data is ‘correctly’ converted into the CMYK data in the color converting apparatus 10, the print image 12a is an image having colors of an impression identical with that of the print image 11a.

In the following description, for mutual distinction, the RGB data on the input side may be referred to as input RGB data or input RGB and the RGB data for the virtual printer 14 may be referred to as dummy RGB data or dummy RGB.

In creating the second link profile for performing the gamut mapping, a printer profile describing a relation between the input RGB representing color reproducibility of the printer 11 and a value (L*a*b* value) on a common color space (here, an L*a*b* color space) and a virtual profile describing a relation between the dummy RGB of a virtual printer having color reproducibility highly matching color reproducibility of the printing system 12 and L*a*b* are required.

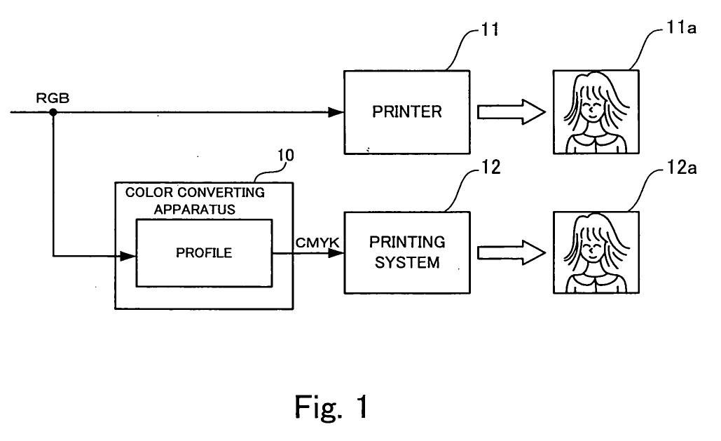

The first link profile for performing the color matching is a link profile describing a relation between the dummy RGB and CMYK. A profile used in the color converting apparatus shown in FIG. 1 is a link profile describing a relation between the input RGB and CMYK. However, in the case of FIG. 2, since the virtual printer is interposed, the first link profile describing the relation between the dummy RGB and CMYK is required.

In the following description, an explanation will be made about a method of creating a color conversion definition (the second link profile and the first link profile shown as blocks in FIG. 2) that can convert RGB data (a coordinate point in an RGB color space) for a printer adapted to the printer 11 into CMYK data (a coordinate point in a CMYK color space) from which the print image 12a, which has an impression of colors highly matching compared with that of the print image 11a obtained when print-outputted in the printer 11 based on the RGB data, can be created even if the RGB data has printability in the printing system 12 and color reproducibility (printer profiles) of the printer 11 and color reproducibility (print profiles) of the printing system 12 are different. In the explanation, a method of creating a virtual profile that highly satisfies a K plate constraint, limitation on a total quantity of ink, and the like will be explained.

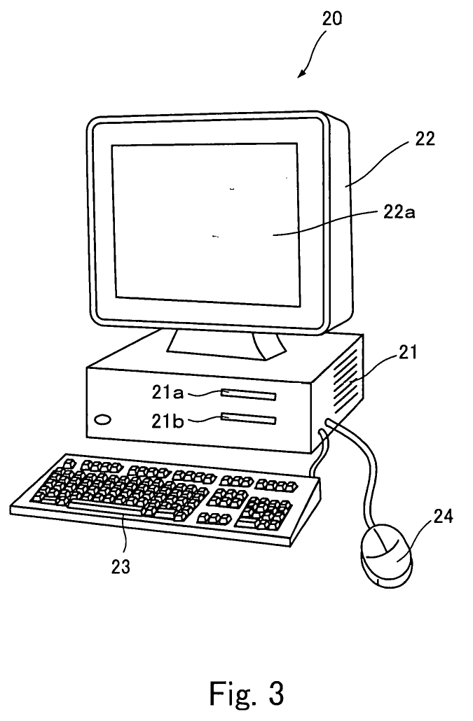

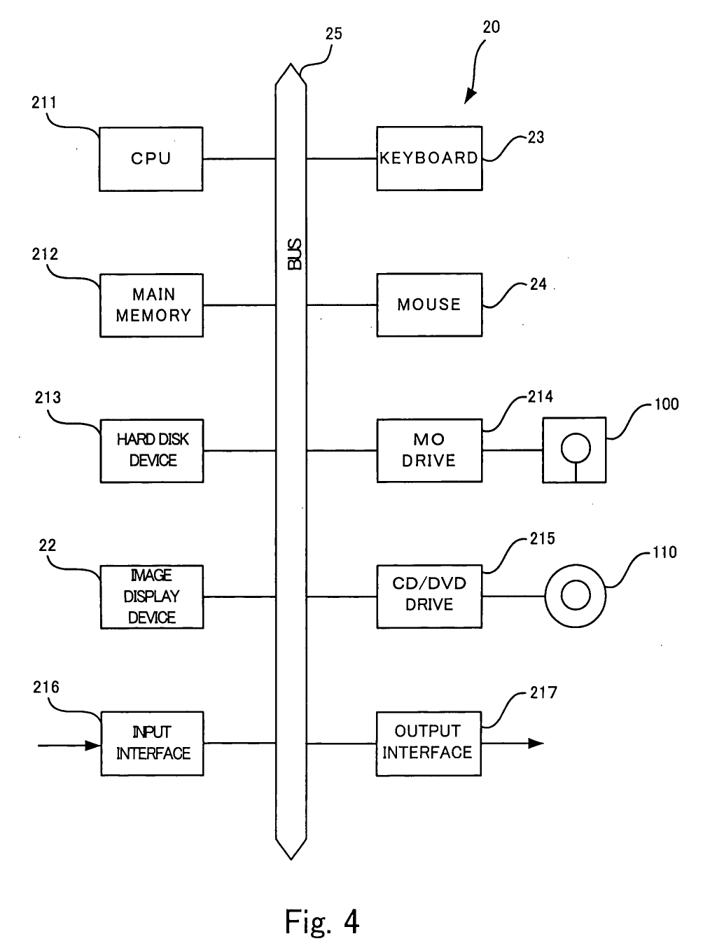

FIG. 3 is an external perspective view of a personal computer 20 forming an embodiment of a color conversion definition creating apparatus according to the invention. FIG. 4 is a hardware diagram of the personal computer. The color conversion definition creating apparatus according to this embodiment includes an embodiment of a profile creating apparatus according to the invention.

The embodiment of the color conversion definition creating apparatus according to the invention (including the embodiment of the profile creating apparatus according to the invention) is formed by hardware and an OS (Operating System) of the personal computer 20 and a color conversion definition creating program (including a profile creating program) installed and executed in the personal computer 20.

It is assumed here that the color converting apparatus 10 shown in FIG. 2 can also be realized by a personal computer and, in this embodiment, the personal computer 20 shown in FIGS. 3 and 4 constituting the color conversion definition creating apparatus according to this embodiment also functions as the color converting apparatus 10 shown in FIG. 2 in terms of hardware. However, it is also possible that the personal computer constituting the color conversion definition creating apparatus is a personal computer different from the personal computer constituting the color converting apparatus 10 shown in FIG. 2 and a color conversion definition created by the color conversion definition creating apparatus is installed in the color converting apparatus 10 in FIG. 2.

In the following description, first, hardware of the personal computer 20 shown in FIGS. 3 and 4 will be explained. Then, an embodiment of a color conversion definition creating method performed using the personal computer 20 will be explained.

As shown in FIG. 3, the personal computer 20 includes, as an external structure, a main body apparatus 21, an image display device 22 that displays an image on a display screen 22a according to an instruction from the main body apparatus 21, a keyboard 23 for inputting various kinds of information corresponding to key operation to the main body apparatus 21, and a mouse 24 for designating an arbitrary position on the display screen 22a to input an instruction corresponding to an icon or the like displayed in the position at the time of the designation. The main body apparatus 21 has, in appearance, an MO inserting port 21a for inserting a magneto-optical disk (MO) and a CD/DVD inserting port 21b for inserting a CD and a DVD.

As shown in FIG. 4, the main body apparatus 21 includes a CPU 211 that executes various programs, a main memory 212 to which a program stored in a hard disk device 213 is read out and in which the program is expanded for execution in the CPU 211, the hard disk device 213 having various programs, data, and the like stored therein, an MO drive 214 that accesses the magneto-optical disk (MO) 100 inserted therein, and a CD/DVD drive 215 that accesses a CD and a DVD (represented by a CD-ROM 110) inserted therein. The personal computer 20 also functions as the color converting apparatus 10 in FIG. 2 and incorporates an input interface 216 that receives RGB data from the outside and an output interface 217 that sends CMYK data to the printing system 12. These components and the image display device 22, the keyboard 23, and the mouse 24 shown in FIG. 3 are connected to one another via a bus 25.

In the CD-ROM 110, a color conversion definition creating program for causing the personal computer 20 to operate as a color conversion definition creating apparatus is stored. The CD-ROM 10 is inserted in the CD/DVD drive 215. The color conversion definition creating program stored in the CD-ROM 110 is uploaded to the personal computer 20 and stored in the hard disk device 213.

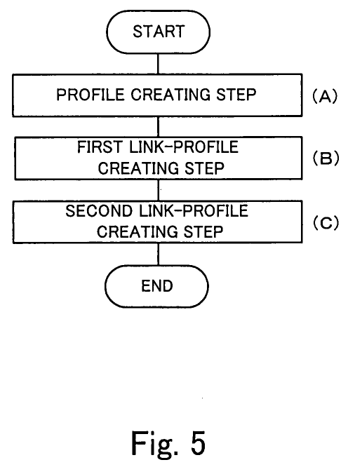

FIG. 5 is a flowchart for explaining an embodiment of the color conversion definition creating method according to the invention.

The color conversion definition creating method is a color conversion definition creating method of creating a color conversion definition for converting a coordinate point in a color reproduction range of the printer 11 in an input RGB color space dependent on a first device (here, the printer 11 shown in FIG. 1), which mediates an image and image data, into a coordinate point in a color reproduction range for printing in a CMYK color space for printing of the printing system 12 shown in FIG. 1.

The color conversion definition creating method includes: a profile creating step (step (A)) of creating a virtual profile between a dummy RGB color space that has a color reproduction range obtained by tracing the color reproduction range for printing and depends on a virtual second device (here, the virtual printer 14 shown in FIG. 2), which mediates an image and image data, and a predetermined common color space (here, an L*a*b* color space); a first link-profile creating step (step (B)) of creating a first link profile for converting a coordinate point in a color reproduction range of the virtual printer 14 in the dummy RGB color space into a coordinate point in the color reproduction range for printing in the CMYK color space; and a second link-profile creating step (step (C)) of creating a second link profile for converting a coordinate point in the color reproduction range of the printer 11 in the input RGB color space into a coordinate point in the color reproduction range of the virtual printer 14 in the dummy RGB color space using printer profiles as profiles of the printer 11 and the virtual profile created in the profile creating step (A).

Details of the color conversion definition creating method shown in FIG. 5 will be described later.

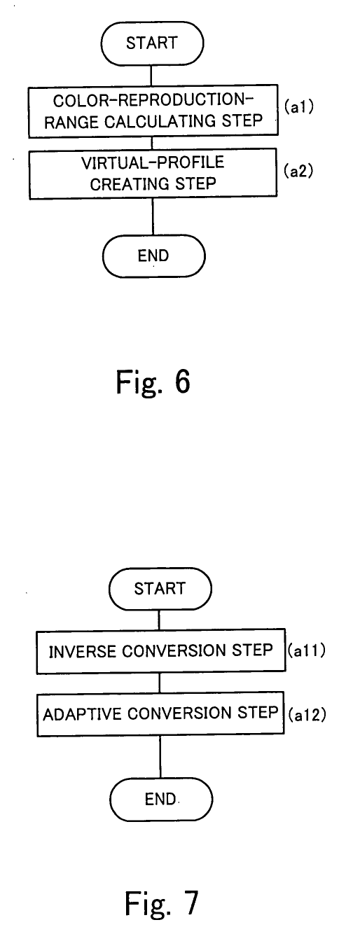

FIG. 6 is a flowchart showing a detailed flow of the profile creating step (step (A)) in the color conversion definition creating method shown in FIG. 5.

The profile creating step in step (A) in FIG. 5 alone forms an embodiment of the profile creating method according to the invention. The profile creating step in step (A) is a profile creating method of creating a virtual profile between a dummy RGB color space dependent on a virtual device (the virtual printer 14 in FIG. 2), which mediates an image and image data, and a predetermined common color space (here, an L*a*b* color space). As shown in FIG. 6, the profile creating step includes a color-reproduction-range calculating step (step (a1)) and a virtual-profile creating step (step (a2)).

In the color-reproduction-range calculating step in step (a1), a printable color reproduction range in the L*a*b* color space, which is obtained by mapping a color reproduction range adjusted for printing in the CMYK color space for printing to the L*a*b* color space, is calculated using an adaptive conversion profile for converting a coordinate point in the CMYK color space for printing into a coordinate point in the L*a*b* color space and an inverse conversion profile for converting a coordinate point in the L*a*b* color space into a coordinate point in the color reproduction range adjusted for printing in the CMYK color space for printing.

In the virtual-profile creating step in step (a2), the printable color reproduction range calculated in the color-reproduction-range calculating step in step (a1) and the dummy RGB color space are linked to create a virtual profile.

FIG. 7 is a diagram showing a detailed flow of the color-reproduction-range calculating step in step (a1) in FIG. 6.

As shown in FIG. 7, the color-reproduction-range calculating step in step (a1) includes an inverse conversion step (step (a11)) and an adaptive conversion step (step (a12)). In the inverse conversion step in step (a11), a coordinate point on the L*a*b* color space is converted into a coordinate point in the color reproduction range adjusted for printing in the CMYK color space using the inverse conversion profile. In the adaptive conversion step in step (a12), the coordinate point in the color reproduction range adjusted to the printing in the CMYK color space obtained in the inverse conversion step is converted into a coordinate point on the L*a*b* color space using the adaptive conversion profile. In the inverse conversion step (step (a11)) and the adaptive conversion step (step (a12)), an A2B1 tag and a B2A1 tag of an ICC profile are used as the adaptive conversion profile and the inverse conversion profile, respectively, to calculate a printable color reproduction range.

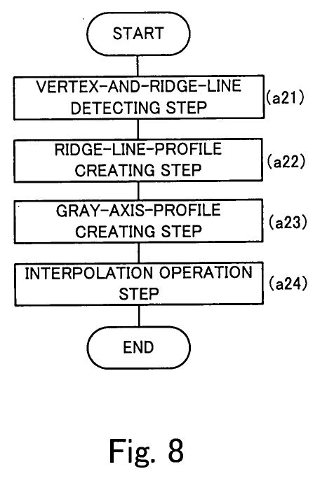

FIG. 8 is a diagram showing a detailed flow of the virtual-profile creating step in step (a2) in FIG. 6.

As shown in FIG. 8, the virtual-profile creating step in step (a2) in FIG. 6 includes a vertex-and-ridge-line detecting step (step (a21)), a ridge-line-profile creating step (step (a22)), a gray-axis-profile creating step (step (a23)), and an interpolation operation step (step a24).

In the vertex-and-ridge-line detecting step in step (a21), respective vertices of W, R, G, B, C, M, Y, and K of the printable color reproduction range in the L*a*b* color space calculated in the color-reproduction-range calculating step (in step (a1) of FIG. 6) and twelve ridge lines in total connecting R and M, M and B, B and C, C and G, G and Y, Y and R, W and C, W and M, W and Y, K and R, K and G, and K and B are detected and the vertices and the ridge lines are associated with vertices and ridge lines corresponding thereto, respectively, in the dummy RGB color space.

More specifically, in the vertex-and-ridge-line detecting step in step (a21), a locus of a color of a maximum chroma in a two-dimensional color reproduction range obtained by projecting the printable color reproduction range on one or more planes is detected and ridge lines connecting R, M, B, C, G, Y, and R in this order are detected. Angles in respective hue angle ranges set for R, M, B, C, G, and Y, respectively, of the ridge lines connecting R, M, B, C, G, Y, and R in order detected on the printable color reproduction range are detected and the angles in the respective hue ranges are associated with the respective vertices of R, M, B, C, G, and Y. Moreover, respective outermost edges connecting respective vertices of R, G, and B and a vertex of K of respective two-dimensional color reproduction ranges obtained by projecting the printable color reproduction range on respective planes including the gray axis (here, an L* axis) and the respective vertices of R, G, and B are set as respective ridge lines connecting the respective vertices of R, G, and B and the vertex of K in the printable color reproduction range. Respective outermost edges connecting a vertex of W and respective vertices of C, M, and Y of respective two-dimensional color reproduction ranges obtained by projecting the printable color reproduction range on the respective planes including the gray axis (here, the L* axis as in the above description) and the respective vertices of C, M, and Y are set as respective ridge lines connecting the vertex of W and the respective vertices of C, M, and Y in the printable color reproduction range.

In the vertex-and-ridge-line detecting step in step (a21), noise removal processing is applied to a ridge line once detected to detect a ridge line with noise reduced. A specific noise reduction processing method will be described later.

In the ridge-line-profile creating step in step (a22) in FIG. 8, a ridge line profile concerning respective ridge lines in which a coordinate point in the dummy RGB color space and a coordinate point in the L*a*b* color space are associated is created such that, when plural points are set at equal intervals on the respective ridge lines on the dummy RGB color space and the plural points are mapped onto the L*a*b* color space, the plural points mapped onto the L*a*b* color space are arranged at equal intervals on the respective ridge lines on the L*a*b* color space.

In the gray-axis-profile creating step in step (a23) in FIG. 8, a gray axis profile concerning the gray axis in which a coordinate point in the dummy RGB color space and a coordinate point in the L*a*b* color space are associated is created such that, when plural points are set at equal intervals on the gray axis connecting the vertex of W and the vertex of K on the dummy RGB space and the plural points are mapped onto the L*a*b* color space, the plural points mapped onto the L*a*b* color space are arranged at equal intervals on the gray line connecting the vertex of W and the vertex of K on the L*a*b* color space.

In the interpolation operation step in step (a24) in FIG. 8, a virtual profile is created by associating a coordinate point in the dummy RGB space and a coordinate point in the L*a*b* color space over the entire dummy RGB color space according to an interpolation operation with the ridge line profile created in the ridge-line-profile creating step in step (a22) and the gray axis profile created in the gray-axis-profile creating step in step (a23) set as boundary conditions.

Details of the profile creating step (step (A) in FIG. 5) shown in FIGS. 6 to 8 will be described later.

In this embodiment, the color conversion definition creating method shown in FIG. 5 (including the profile creating method shown in FIG. 6) is carried out when an embodiment of the color conversion definition creating program according to the invention is installed in the personal computer 20 shown in FIGS. 2 and 3 and executed.

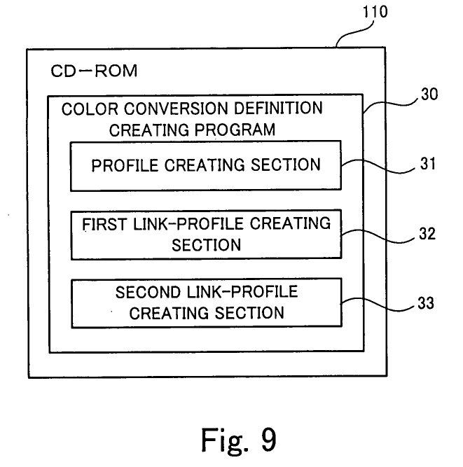

FIG. 9 is a schematic diagram of an embodiment of a color conversion definition creating program 30 according to the invention.

The color conversion definition creating program 30 shown in FIG. 9 is stored in the CD-ROM 110 shown in FIG. 4 as well. The color conversion definition creating program is installed in the personal computer 20 shown in FIGS. 3 and 4 from the CD-ROM 110, executed in the personal computer 20, and causes the personal computer 20 to operate as a color conversion definition creating apparatus that creates a color conversion definition for converting a coordinate point in a color reproduction range of the printer 11, which mediates an image and image data, in a first RGB color space dependent on the first device (here, the printer 11 in FIG. 2) into a coordinate point in a color reproduction range for printing in a CMYK color space for printing.

The color conversion definition creating program 30 includes a profile creating section 31, a first link-profile creating section 32, and a second link-profile creating section 33. The profile creating section 31, the first link-profile creating section 32, and the second link-profile creating section 33 are program components that cause, when the color conversion definition creating program 30 shown in FIG. 9 is installed in the personal computer 20 shown in FIGS. 3 and 4 and executed, the personal computer 20 to carry out the profile creating step in step (A), the first link-profile creating step in step (B), and the second link-profile creating step in step (C) of the color conversion definition creating method shown in FIG. 5, respectively. The profile creating section 31, the first link-profile creating section 32, and the second link-profile creating section 33 are explained in detail later.

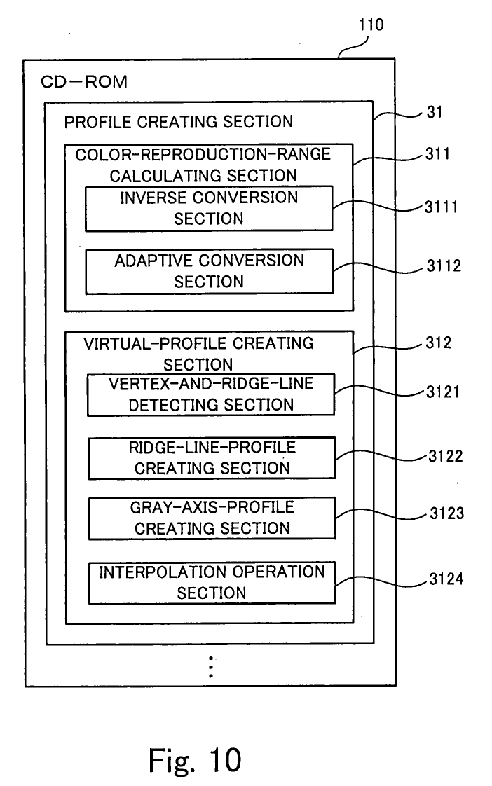

FIG. 10 is a schematic diagram of the profile creating section 31, which is one program component in the color conversion definition creating program 30 shown in FIG. 9.

The profile creating section 31 shown in FIG. 10 includes a color-reproduction-range calculating section 311 and a virtual-profile creating section 312. The color-reproduction-range calculating section 311 includes an inverse conversion section 3111 and an adaptive conversion section 3112. The virtual-profile creating section 312 includes a vertex-and-ridge-line detection section 3121, a ridge-line-profile creating section 3122, a gray-axis-profile creating section 3123, and an interpolation operation section 3124.

The color-reproduction-range calculating section 311 (the inverse conversion section 3111 and the adaptive conversion section 3112) and the virtual-profile creating section 312 (the vertex-and-ridge-line detecting section 3121, the ridge-line-profile creating section 3122, the gray-axis-profile creating section 3123, and the interpolation operation section 3124) are program components that cause, when the profile creating section 31 shown in FIG. 10 is installed in the personal computer 20 shown in FIGS. 3 and 4 and executed, the personal computer 20 to carry out the color-reproduction-range calculating step in step (a1) (the inverse conversion step and the adaptive conversion step in steps (a11) to (a12) in FIG. 7) and the virtual-profile creating step in step (a2) (the vertex-and-ridge-line detecting step, the ridge-line-profile creating step, the gray-axis-profile creating step, and the interpolation operation step in steps (a21) to (a24) in FIG. 8) in the profile creating step shown in FIG. 6, respectively, and are also program components that realizes the profile creating step in step (A) of the color conversion definition creating method in FIG. 5 as a whole. The color-reproduction-range calculating section 311 (the inverse conversion section 3111 and the adaptive conversion section 3112) and the virtual-profile creating section 312 (the vertex-and-ridge-line detecting section 3121, the ridge-line-profile creating section 3122, the gray-axis-profile creating section 3123, and the interpolation operation section 3124) will be explained in detail later.

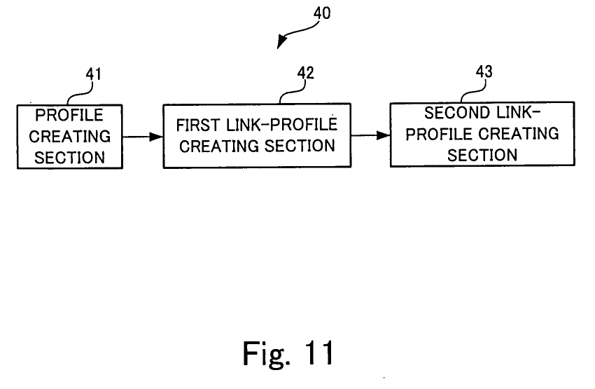

FIG. 11 is a functional diagram of an embodiment of the color conversion definition creating apparatus according to the invention.

A color conversion definition creating apparatus 40 shown in FIG. 11 is established in the personal computer 20 when the color conversion definition creating program 30 is installed in the personal computer 20 shown in FIG. 4 from the CD-ROM 110 shown in FIG. 9 and executed. The color conversion definition creating apparatus 40 includes a profile creating section 41, a first link profile creating section 42, and a second link profile creating section 43. The profile creating section 41, the first link-profile creating section 42, and the second link-profile creating section 43 are functions that are realized when the profile creating section 31, the first link-profile creating section 32, and the second link-profile creating section 33 of the color conversion definition creating program 30 shown in FIG. 9 are executed in the personal computer 20, respectively. These sections will be explained in detail later.

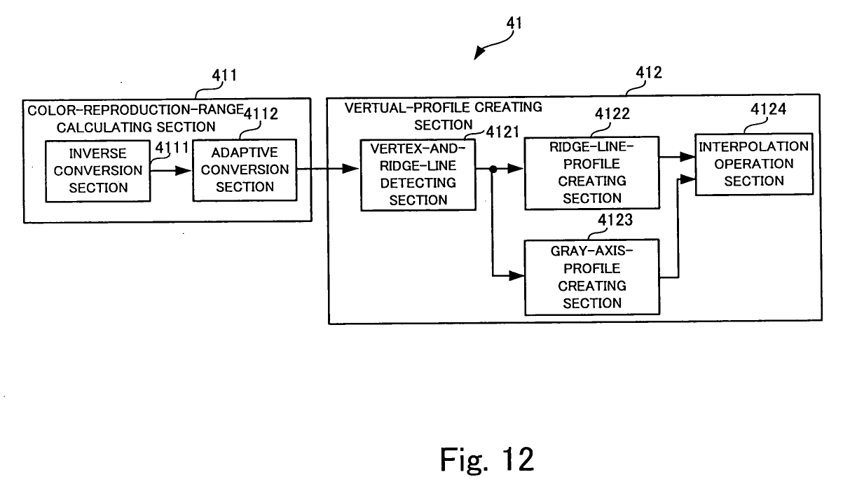

FIG. 12 is a functional diagram of the profile creating section 41 in the color conversion definition creating apparatus 40 shown in FIG. 11.

The profile creating section 41 includes a color-reproduction-range calculating section 411 and a virtual-profile creating section 412. The color-reproduction-range calculating section 411 includes an inverse conversion section 4111 and an adaptive conversion section 4112. The virtual-profile creating section 412 includes a vertex-and-ridge-line detecting section 4121, a ridge-line-profile creating section 4122, a gray-axis-profile creating section 4123, and an interpolation operation section 4124.

The color-reproduction-range calculating section 411 (the inverse conversion section 4111 and the adaptive conversion section 4112) and the virtual-profile creating section 412 (the vertex-and-ridge-line detecting section 4121, the ridge-line-profile creating section 4122, the gray-axis-profile creating section 4123, and the interpolation operation section 4214) are functions that are realized when the color-reproduction-range calculating section 311 (the inverse conversion section 3111 and the adaptive conversion section 3112) and the virtual-profile creating section 312 (the vertex-and-ridge-line detecting section 3121, the ridge-line-profile creating section 3122, the gray-axis-profile creating section 3123, and the interpolation operation section 3124) of the profile creating section 31 as a program component shown in FIG. 10 are executed in the personal computer 20. These sections will be explained in detail later.

In the following description, the color conversion definition creating method shown in FIG. 5, the color conversion definition creating program 30 shown in FIG. 9, and the color conversion definition creating apparatus 40 shown in FIG. 11 explained above are collectively explained. The profile creating step in step (A) in FIG. 5 (the profile creating section 31 in FIG. 9 and the profile creating section 41 in FIG. 11), the first link-profile creating step in step (B) in FIG. 5 (the first link-profile creating section 32 in FIG. 9 and the first link-profile creating section 42 in FIG. 11), and the second link-profile creating step in step (C) in FIG. 5 (the second link-profile creating section 33 in FIG. 9 and the second link-profile creating section 43 in FIG. 11) of the color conversion definition creating method (the color conversion definition creating program 30 and the color conversion definition creating apparatus 40) will be explained in detail. In the detailed explanation, details of the profile creating method in FIGS. 6 to 8 (the profile creating section 31 in FIG. 10 and the profile creating section 41 in FIG. 12), which is an embodiment of the profile creating method (the profile creating program and the profile creating apparatus) according to the invention will also be explained.

In the following description, an explanation will be made citing the color conversion definition creating method and the profile creating method shown in FIGS. 5 to 8. However, the methods are cited to indicate steps of the explanation (which point is explained). Thus, the explanation applies not only to the methods but also the programs and the apparatuses in common.

It is assumed that, as a premise for executing the color conversion definition creating method in FIGS. 5 to 8, the adaptive conversion profile and the inverse conversion profile forming the printer profiles and the print profiles explained below have been acquired.

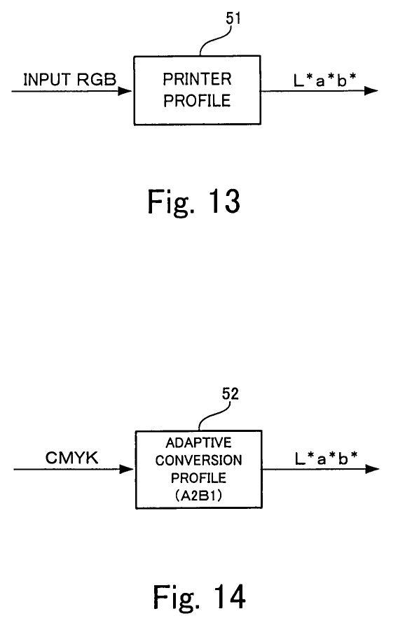

FIG. 13 is a conceptual diagram of a printer profile.

A printer profile 51 shown in FIG. 13 is a profile of the printer 11 shown in FIG. 2 and associates RGB data inputted to the printer 11 (as described above, represented as input RGB) with colors on the image 11a print-outputted by the printer 11 (here, L*a*b* values). Here, it is possible to acquire the printer profile 51 in a form of an LUT (Look-Up Table).

A detailed explanation of a method of creating the printer profile 51 is omitted because the method is well known. Input RGB data obtained by changing values of R, G, and B in various ways is inputted to the printer 11, a color chart including a large number of color patches is print-outputted, and the respective color patches forming the color chart are measured by a calorimeter to obtain colorimetric values (L*a*b* values) of the respective color patches. Basically, in the printer profile 51, the input RGB values are associated with the calorimetric values (L*a*b* values) obtained in this way.

FIG. 14 is a conceptual diagram of the adaptive conversion profile (the A2B1 profile) of the print profiles.

The A2B1 profile 52 shown in FIG. 14 is a profile of the printing system shown in FIG. 2 and is an adaptive conversion profile for converting CMYK data inputted to the printing system 12 into colors (L*a*b* values) of the image 12a on a print surface printed by the printing system 12. The print profile 52 is also acquired in a form of an LUT (Look-Up Table). An explanation of the method of creating the print profile 52 is omitted because the method is principally the same as the method of creating the printer profile 51 in FIG. 13 and well known.

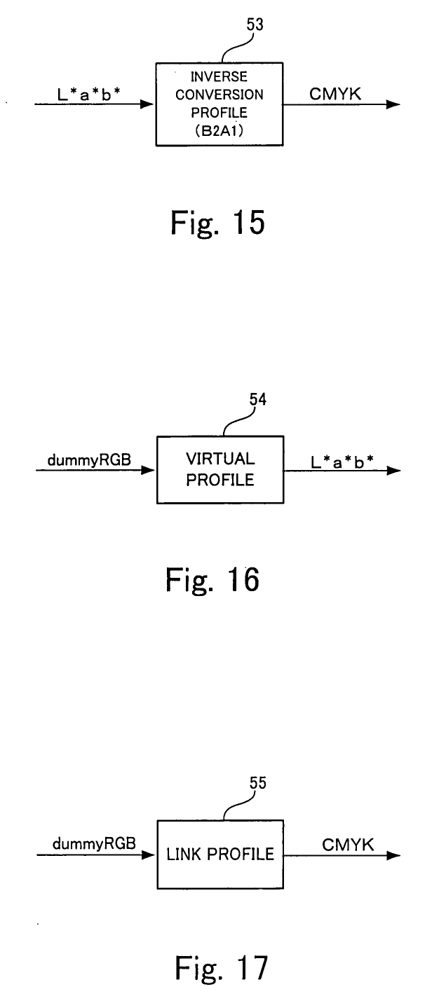

FIG. 15 is a conceptual diagram of the inverse conversion profile (the B2A1 profile) in the print profiles.

Like the A2B1 profile 52 shown in FIG. 14, a B2A1 profile 53 shown in FIG. 15 is a profile of the printing system shown in FIG. 2. However, contrary to the A2B1 profile shown in FIG. 14, the B2A1 profile 53 shown in FIG. 15 is an inverse conversion profile for converting an L*a*b* value into a CMYK value.

The B2A1 profile 53 shown in FIG. 15 is a profile targeting calorimetric coincidence. As the inverse conversion profile, other than this B2A1 profile, there are a B2A0 profile targeting perceptive coincidence and a B2A2 profile emphasizing a chroma. However, since it is an object to acquire only separation information excluding unnecessary gamut conversion and the B2A1 profile is most suitable for this purpose. Thus, the B2A1 profile is adopted in this embodiment.

In the B2A1 profile shown in FIG. 15, CMYK values are defined for the entire area of the L*a*b* color space including colors that cannot be represented by the printing system 12 shown in FIG. 2. CMYK values of a boundary of a color reproduction range satisfying a K plate constraint and limitation on a total quantity of ink, which can be represented by the printing system 12, are associated with the L*a*b* values representing the colors, which cannot be represented by the printing system 12.

FIG. 16 is a conceptual diagram of a virtual profile created in the profile creating step in step (A) of the color conversion definition creating method in FIG. 5 explained below.

A virtual profile 54 shown in FIG. 16 is a profile of the virtual printer 14 shown in FIG. 2 and is an LUT that associates RGB data inputted to the printer 14 (as described above, for distinction from RGB data inputted to the printer 11 shown in FIG. 2, represented as dummy RGB) with colors (L*a*b* values) on an image print-outputted by the printer 14. However, the virtual profile 54 is a profile of the virtual printer 14 and logically created as described later.

FIG. 17 is a conceptual diagram of a link profile, created in the first link-profile creating step in step (B) of the color conversion definition creating method in FIG. 5. The link profile will be described later in detail.

A link profile 55 shown in FIG. 17 is equivalent to the first link profile in the color conversion definition creating method according to the invention. The link profile 55 is an LUT indicating a correspondence relation between dummy RGB value, i.e., value of RGB data inputted to the virtual printer 14 in FIG. 2 and CMYK value, i.e., values of CMYK data inputted to the printing system 12 in FIG. 2.

In the profile creating step (step (A)) of the color conversion definition creating method in FIG. 5, the color-reproduction-range calculating step (step (a1)) and the virtual-profile creating step (step (a2)) shown in FIG. 6 are sequentially carried out to create the virtual profile 54, the concept of which is shown in FIG. 16. Details of these steps will be hereinafter explained.

In the color-reproduction-range calculating step (step (a1)) in FIG. 6, the inverse conversion step (step (a11)) and the adaptive conversion step (step (a12)) shown in FIG. 7 are carried out.

In the inverse conversion step (step (a11)), coordinate values (L*a*b* values) of respective points in the entire area of an L*a*b* color space are converted into coordinate values (CMYK values) in a CMYK color space with reference to the B2A1 profile 53, the concept of which is shown in FIG. 15.

As described above, in the B2A1 profile shown in FIG. 15, CMYK values are defined for the entire area of the L*a*b* color space including colors that cannot be represented by the printing system 12 shown in FIG. 2. CMYK values of a boundary of a color reproduction which can be represented by the printing system 12, are associated with the L*a*b* values representing the colors, which cannot be represented by the printing system 12. Therefore, when the entire area of the L*a*b* color space is converted into CMYK values with reference to the B2A1 profile 53, a set of the CMYK values represents a color reproduction range adjusted for printing in the printing system 12 satisfying printability of the printing system 12.

Subsequently, in the adaptive conversion step (step (a12)) in FIG. 7, the CMYK values of the respective points of the entire color reproduction range adjusted for printing in the printing system 12 in FIG. 2 obtained in the inverse conversion step in step (a11) are converted into L*a*b* values representing coordinate points in the L*a*b* color space with reference to the A2B1 profile, the concept of which is shown in FIG. 14. Then, according to a set of the L*a*b* values, a printable color reproduction range in the L*a*b* obtained by mapping the color reproduction range adjusted for printing in the printing system 12 in the CMYK color space for printing to the L*a*b* color space is obtained.

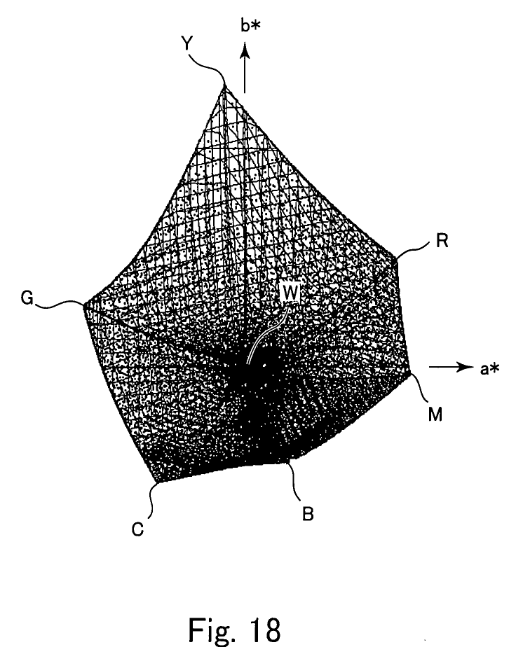

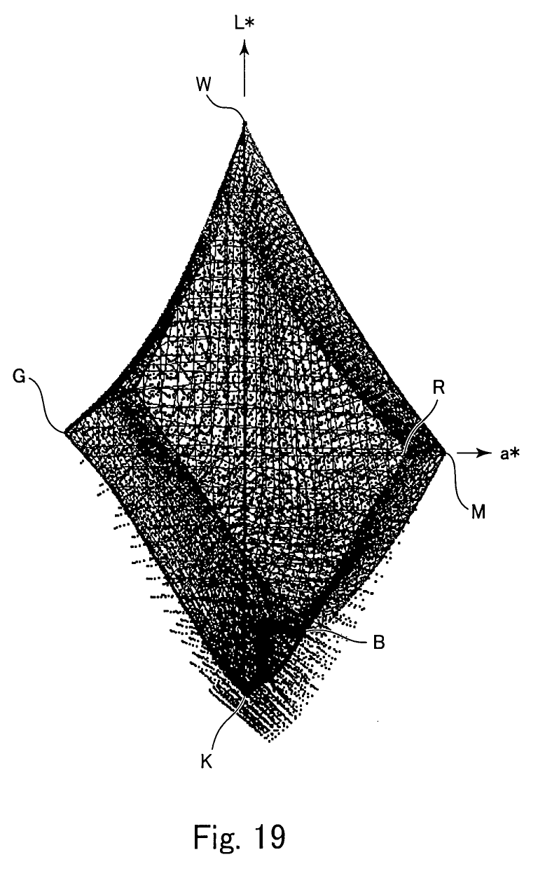

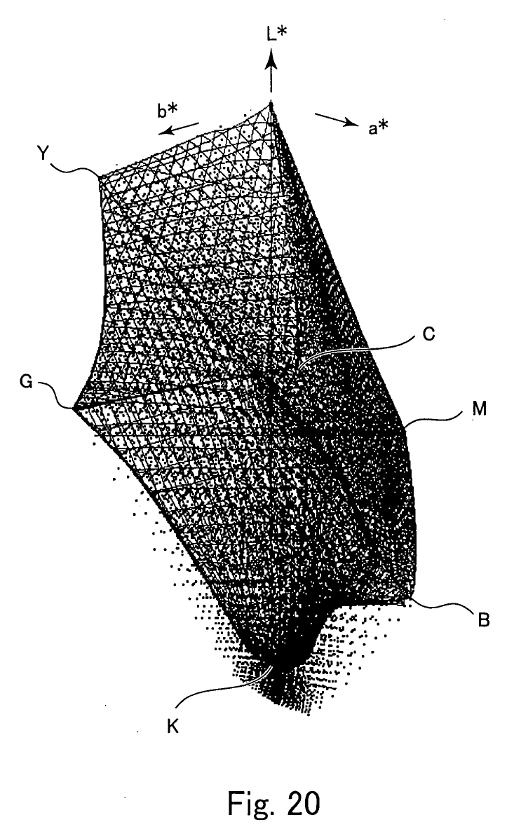

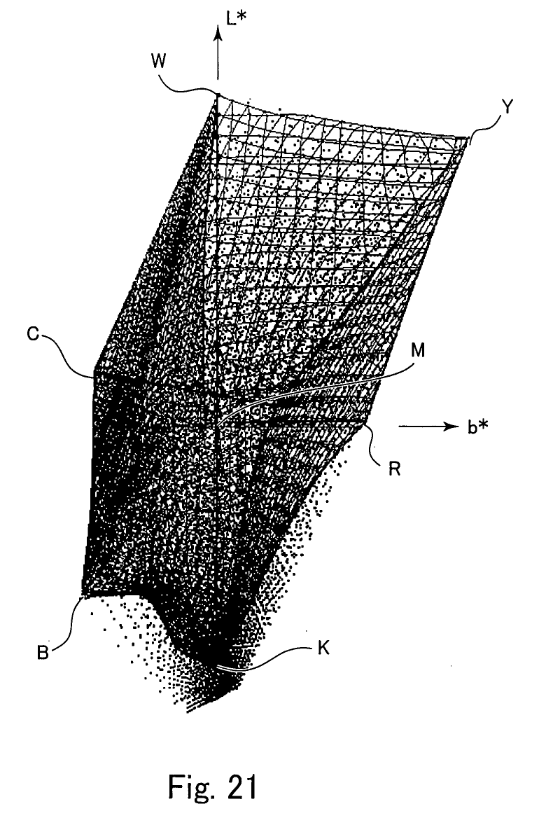

FIGS. 18 to 21 are diagrams of a color reproduction range (dots) represented by the A2B1 profile and the printable color reproduction range calculated through the steps, i.e., a color reproduction range (mesh) represented by the B2A1 profile in a state in which the color reproduction ranges are overlapped and viewed from various angles.

It is sent that, since the printable color reproduction range (the color reproduction range (mesh) represented by the B2A1 profile) is more restricted by limitation of a total quantity of ink and the like, the printable color reproduction range is smaller than the color reproduction range (dots) represented by the A2B1 profile. A correspondence relation between L*a*b* values and CMYK values concerning the color reproduction range represented by the B2A1 profile satisfies a K plate constraint designated by the user.

In the color-reproduction-range calculating step (step (a1)) in FIG. 6, as described above, the printable color reproduction range (the color reproduction range of the B2A1 profile) is calculated.

The virtual-profile creating step (step (a2)) in FIG. 6 will be explained.

In the virtual-profile creating step (step (a2)), the vertex-and-ridge-line detecting step (step (a21)), the ridge-line-profile creating step (step (a22)), the gray-axis-profile creating step (step (a23)), and the interpolation operation step (step (a24)) shown in FIG. 8 are carried out.

First, in the vertex-and-ridge-line detecting step (step (a21)), the printable color reproduction range (the color reproduction range of the B2A1 profile) calculated in the color-reproduction-range calculating step in step (a1) in FIG. 6 is basically projected on an a*-b* plane. A locus of a color with a maximum chroma in a two-dimensional color reproduction range obtained by the projection, i.e., a locus of an outermost edge of the two-dimensional color reproduction range is detected.

In FIG. 18, the two-dimensional color reproduction range projected on the a*-b* plane is shown. Respective vertices of R, M, B, C, G, and Y are shown on the two-dimensional color reproduction range.

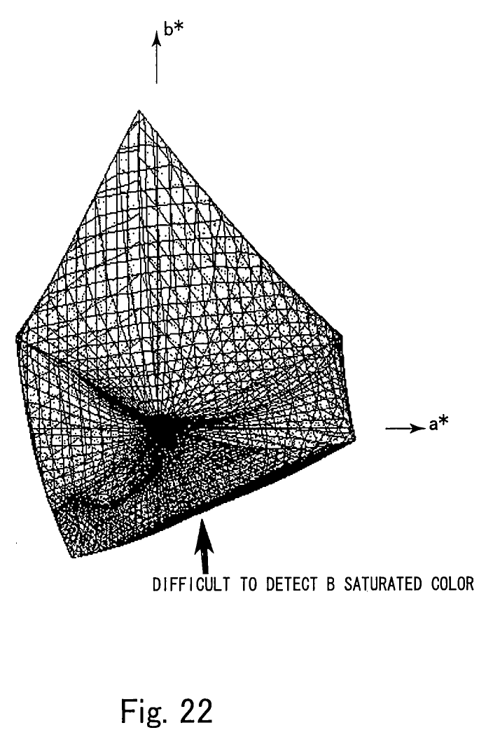

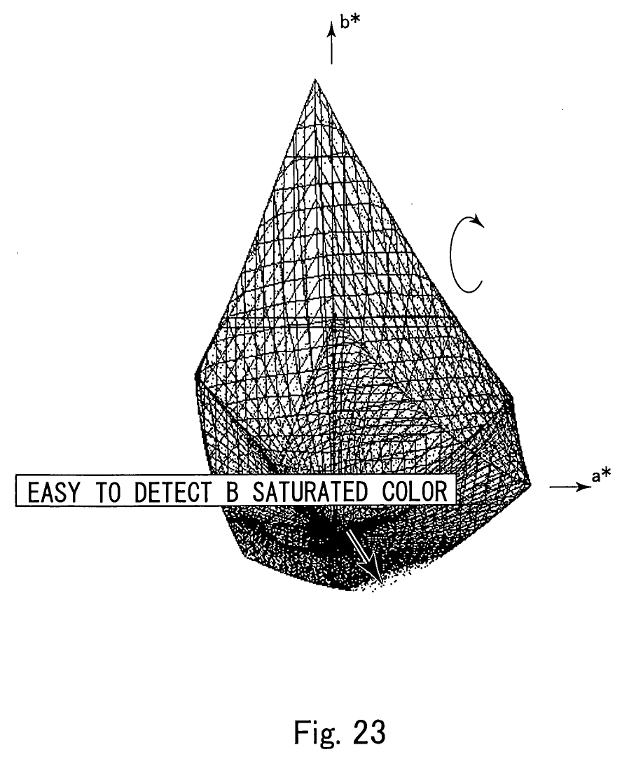

FIG. 22 is a diagram showing a two-dimensional color reproduction range obtained by projecting a color reproduction range different from the color reproduction range shown in FIGS. 18 to 21 on the a*-b* plane. FIG. 23 is a diagram showing a two-dimensional color reproduction range obtained by rotating a three-dimensional color reproduction range on the L*a*b* color space, which is the same as the color reproduction range shown in FIG. 22, −20° around an a* axis in a right-handed thread direction and then projecting the color reproduction range on the a*-b* plane. In FIG. 23, rotating the three-dimensional range −20° around the a* axis in the right-handed thread direction and then projecting the color reproduction range on the a*-b* plane means that the three-dimensional color reproduction range before the rotation is projected on a plane inclined +20° around the a* axis in the right-handed thread direction from the a*-b* plane.

In the case of the color reproduction range shown in FIGS. 22 and 23, if the color reproduction range is projected on the a*-b* plane without being rotated, it is difficult to detect a saturated color of B (a vertex of B) as shown in FIG. 22. Depending on a shape of a color reproduction range, it may be difficult to detect a saturated color of B simply by projecting the color reproduction range on the a*-b* plane in this way. Thus, in this embodiment, basically, saturated colors of respective colors of ridge lines connecting R-M-B-C-G-Y-R in order are detected from a two-dimensional shape projected on the a*-b* plane. However, concerning detection of the saturated color of B (the vertex of B) and ridge lines near B, as shown in FIG. 23, the saturated color is detected using the two-dimensional color reproduction range obtained by rotating the color reproduction range and then projecting the color reproduction range on the a*-b* plane.

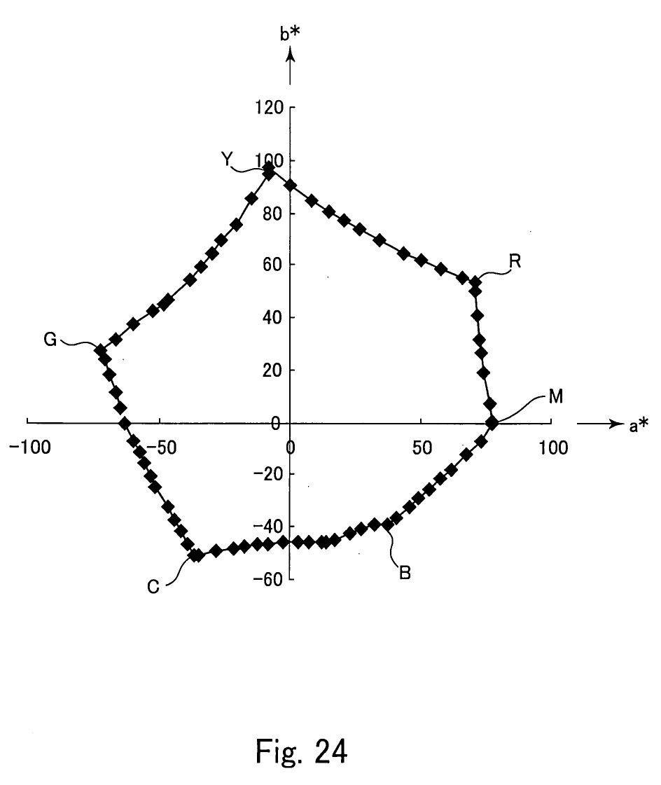

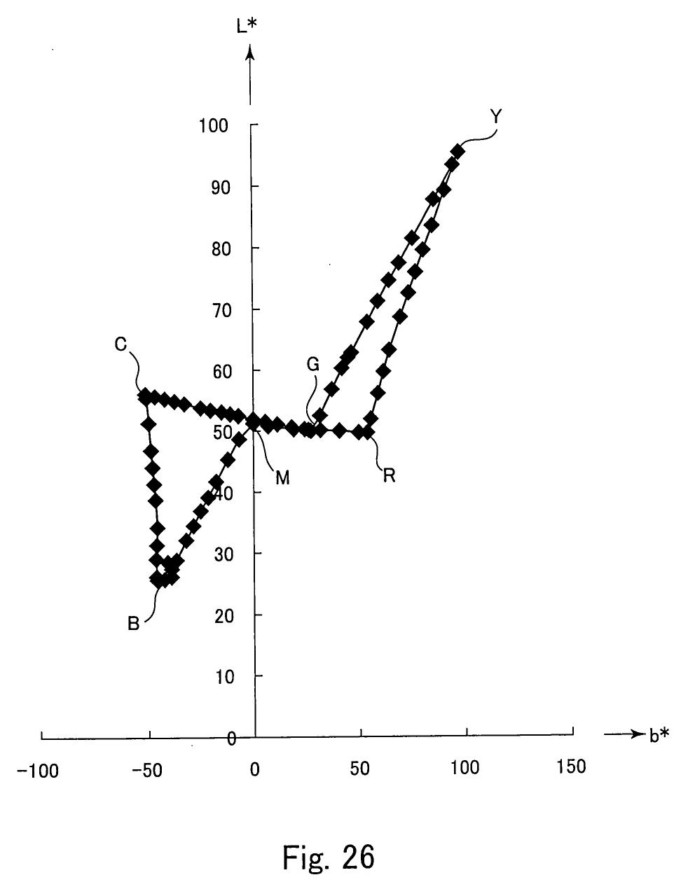

FIGS. 24 to 26 are diagrams of ridge lines connecting R-M-B-C-G-Y-R in order calculated from a locus of a color with a maximum chroma of the color reproduction range projected on the plane as described above in a state in which the ridge lines are viewed from various angles.

The two-dimensional color reproduction range projected on the a*-b* plane shown in FIG. 18 are sectioned for respective predetermined hue angle areas (here, at 5 degrees), color points with a maximum chroma are detected from the respective hue angle areas, and the color points are sequentially connected by straight lines.

Filtering processing concerning a locus of a color with a maximum chroma once detected as described above will be explained.

When the method described above is adopted, color points having extremely close hues may be detected. In detection of saturated colors (vertices) of R, M, B, C, G, and Y described later, an algorithm for detecting the saturated colors using a difference vector between adjacent color points is adopted. However, when color points having extremely close hues are detected, a difference vector of the color points is likely to have a large error. This leads to misdetection of saturated colors.

When hues of adjacent two color points among color points with a maximum chroma detected for the respective hue angle areas are extremely close (in the case of a hue angle within 0.5 degrees), one color point with a lower chroma among the two adjacent colors is removed as noise.

Further, color points having extremely low chromas compared with chromas of the adjacent colors are removed as noise.

Workmanship of a profile is substantially different depending on ability of a maker of the profiler. The noise removal by comparison of chromas is effective for a profile with poor workmanship.

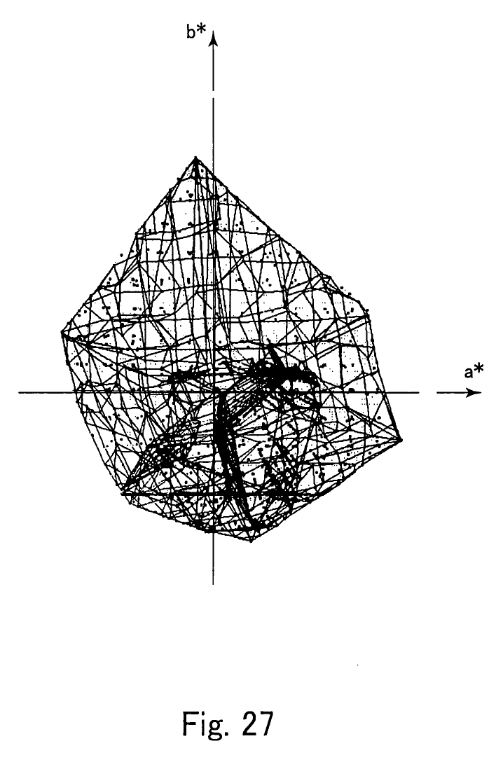

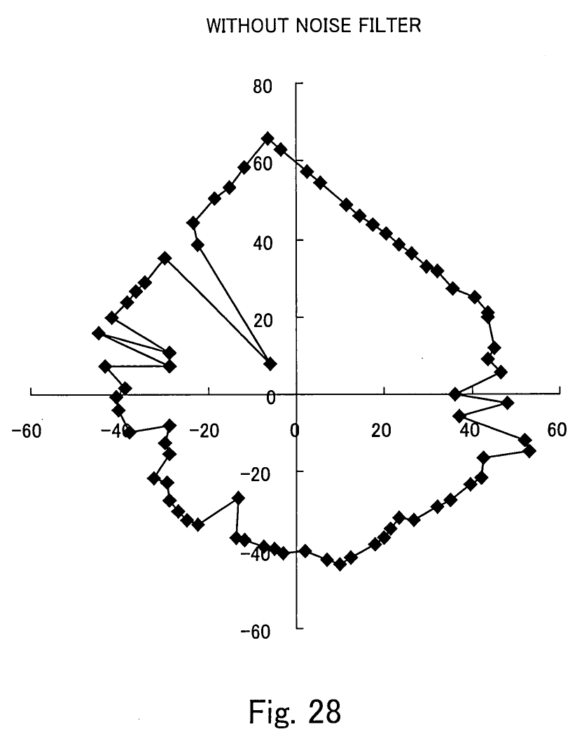

FIG. 27 is a diagram showing an example of a color reproduction range, for which the noise removal by comparison of chromas is effective, projected on the a*-b* plane. FIG. 28 is a diagram obtained by extracting color points with a maximum chroma at each predetermined angle (here, 5 degrees) from the color reproduction range shown in FIG. 27 and plotting the color points.

As it is seen from FIG. 28, evidently, a color with a low chroma in the color reproduction range is misdetected as a color with a maximum chroma. Thus, a ratio of a chroma of one color point on FIG. 28 and chromas of two color points on both sides of the color point (here, a chroma of a point with a higher chroma of the two points on both the sides) is calculated and, when the ratio is equal to or lower than a threshold set in advance, the color point with the low chroma is removed as noise. By performing this arithmetic operation for the respective color points, the color with the low chroma in the color reproduction range is removed.

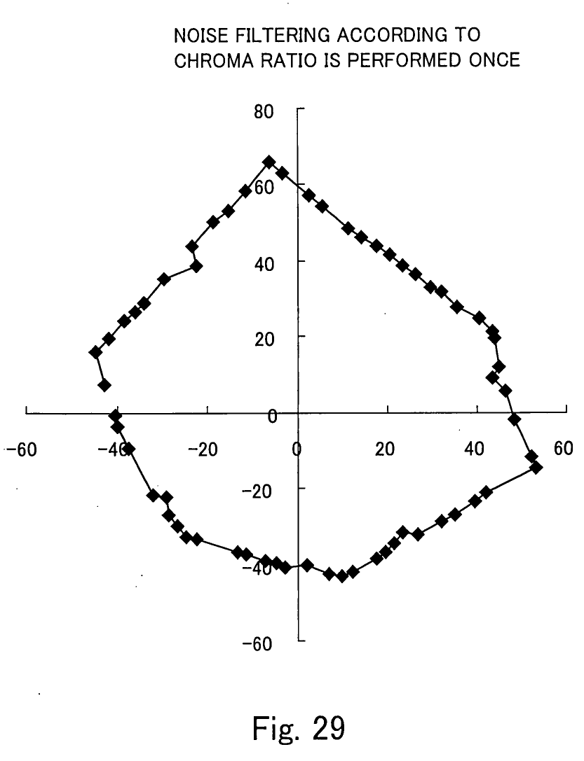

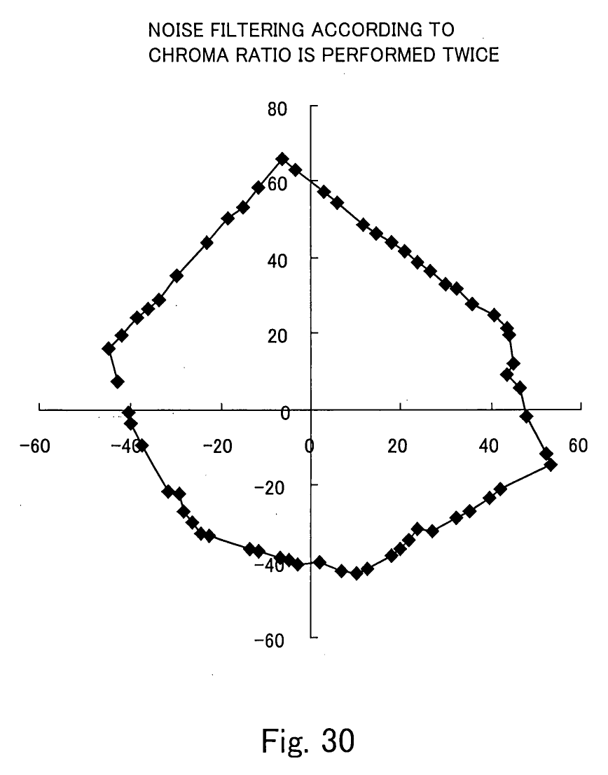

FIG. 29 is a diagram showing a locus of a color with a maximum chroma after the filtering operation for performing noise removal according to a chroma ratio is performed once. FIG. 30 is a diagram showing a locus of the color with the maximum chroma after the same filtering operation is performed twice.

When the filtering processing according to a chroma ratio is repeated plural times, even if a locus of a color with a maximum chroma detected at first is considerably rough as shown in FIG. 28, it is possible to detect a correct locus of the color with the maximum chroma.

Here, after the two kinds of filtering processing is performed, filtering processing for removing a color zigzag in an L* direction as noise is further performed.

In this filtering processing, after applying the two kinds of noise filters to color points, a difference vector between each of the color points remaining without being removed by the noise filters and a color point of a hue adjacent to the color point is calculated. The color point is judged according to a sign of an L* component of this difference vector. In other words, signs of L* components of adjacent difference vectors continuously take maximum and minimum, color points of these two extreme values are discarded as noise.

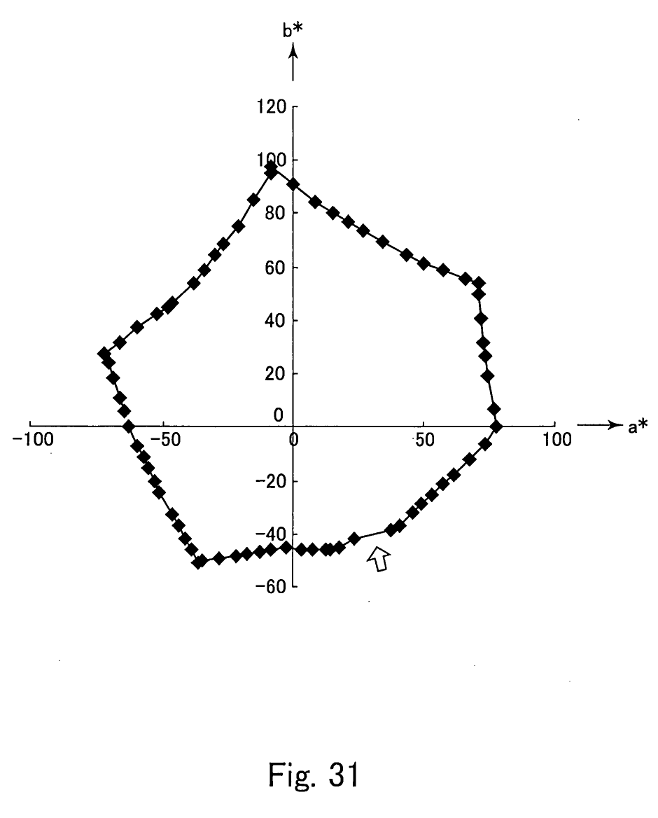

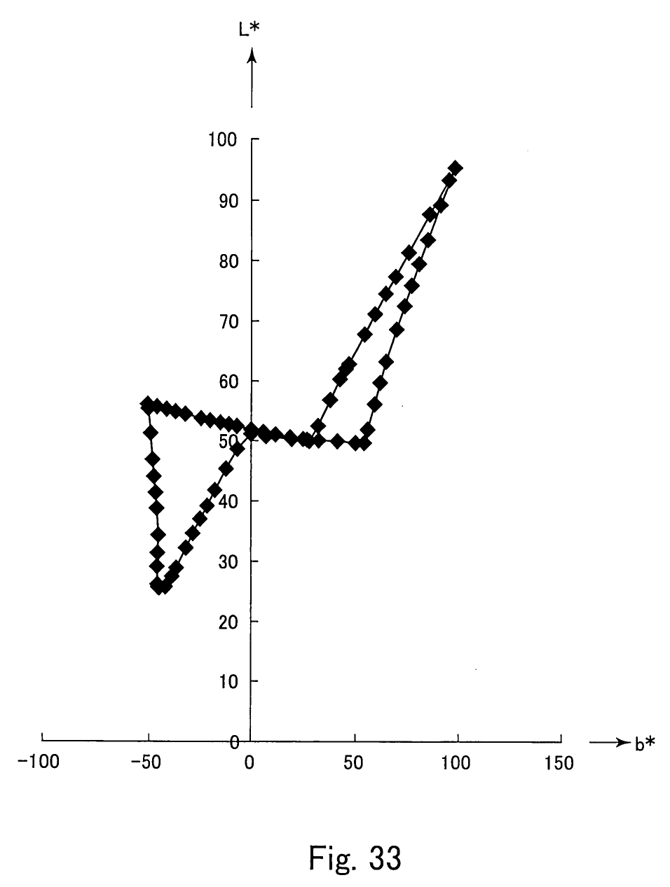

FIGS. 31 to 33 are diagrams of a locus of a color remaining after the three kinds of filtering processing in a state in which the locus is viewed from various angles.

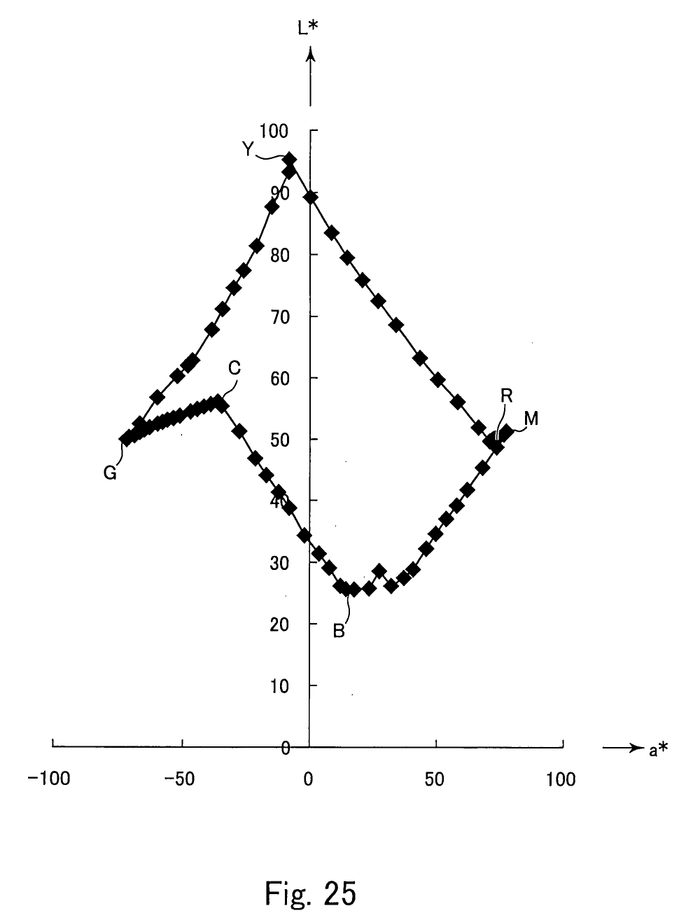

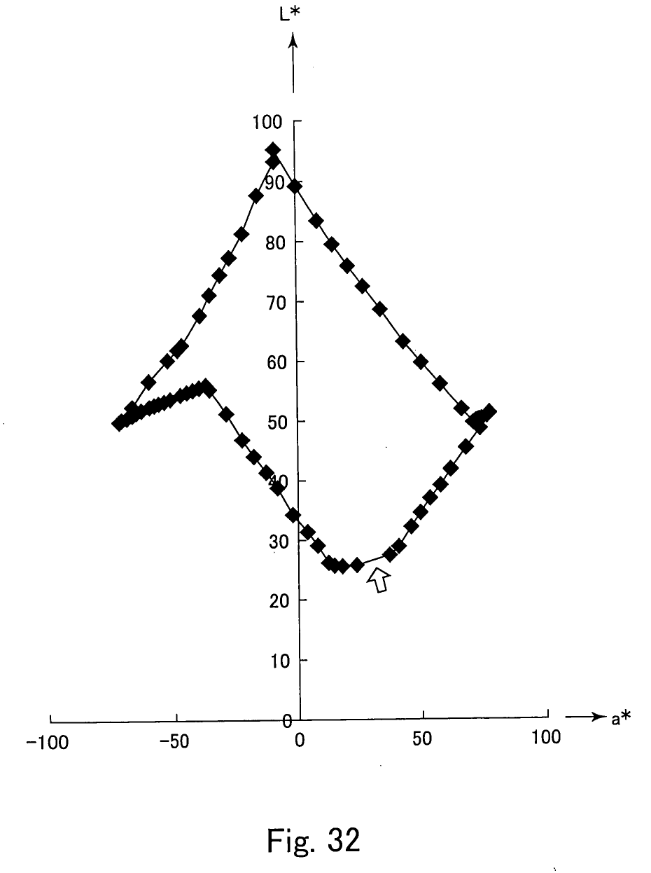

FIGS. 31 and 32 are diagrams corresponding to FIGS. 24 and 25 before the noise removal, respectively. When FIGS. 31 and 32 are compared with FIGS. 24 and 25, it is seen that a color point in a part indicated by arrows in FIGS. 31 and 32 is removed by the noise removal processing according to the sign judgment of the L* component.

In this embodiment, the three kinds of filtering processing are performed and a locus connecting the remaining color points in order forms six ridge lines connecting R-M-B-C-G-Y-R in order excluding six ridge lines connecting R, G, and B and K, respectively, and connecting C, M, and Y and W, respectively.

However, at this stage, saturated colors (vertices) of R, M, B, C, G, and Y are not detected yet. Subsequently, six saturated colors (vertices) of R, M, B, C, G, and Y are detected from a connected line of the six ridge lines detected as described above.

As an example, hue angle areas are set for the respective six colors as follows. In detecting vertices (saturated colors) of the respective colors, detection processing is performed in the hue angle areas of the respective colors. The hue angle areas are set as described below because it is known from experiences that the saturated colors of the respective colors are present only in the hue angle areas of the respective colors.

Here, a minus direction of an a* axis is set as 0 degree of a hue angle and hue angles are defined counterclockwise around the L* axis.

| | |
|---|---|
| C: hue angle range | 20 to 80 degrees |
| B: hue angle range | 80 to 140 degrees |
| M: hue angle range | 140 to 200 degrees |
| R: hue angle range | 200 to 250 degrees |
| Y: hue angle range | 250 to 310 degrees |
| G: hue angle range | 310 to 360 degrees and 0 to 20 degrees |

In this embodiment, as a method of detecting the saturated colors (vertices) of the six colors, the following two kinds of detection methods are adopted.

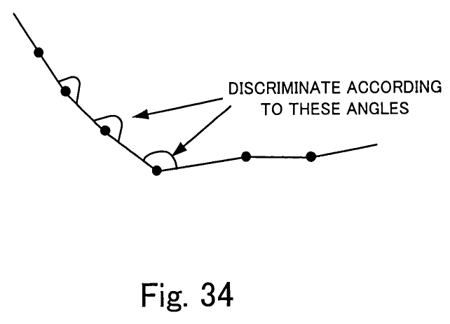

FIG. 34 is a schematic diagram showing one of the two kinds of methods of detecting saturated colors.

Here, it is assumed that, in the connected line of the ridge lines connecting the six saturated colors (see FIGS. 31 to 33), a point where an angle formed by three-dimensional vectors connecting adjacent colors in the L*a*b* color space is a minimum angle in the hue angle areas set for the respective colors is set as a saturated color.

However, it is difficult to judge an angle for the saturated angle of B. It is likely that noise is mixed when the saturated color of B is detected by the detection method described above. Thus, here, a color with lowest brightness in the hue angle area set for B is set as the saturated color of B.

As described above, the six ridge lines connecting R, Y, G, C, B, M, and R in order and the six saturated colors (vertices) of R, G, B, C, M, and Y are detected.

Subsequently, L*a*b* values of W and K are calculated.

For W, a CMYK value corresponding to (L*a*b*)=(100, 0, 0) in the B2A1 profile (see FIG. 15) is calculated. The CMYK value is converted into an L*a*b* value with reference to the A2B1 profile (see FIG. 14).

As described above, concerning an L*a*b* value deviating from a color reproduction range suitable for printing, the B2A1 profile is clipped to a point of a boundary of the color reproduction range suitable for the printing. Thus, a CMYK value representing a point of W in the color reproduction range suitable for printing is calculated by converting (L*a*b*)=(100, 0, 0) into a CMYK value. Subsequently, when this CMYK value is converted into an L*a*b* value with reference to the A2B1 profile, the L*a*b* value is a value representing a vertex of W in a color reproduction range satisfying printability.

Similarly, for K, (L*a*b*)=(100, 0, 0) is converted into a CMYK value with reference to the B2A1 profile (see FIG. 15) and the CMYK value is converted into an L*a*b* value with reference to the A2B1 profile. The L*a*b* value calculated in this way represents a vertex of K in a color reproduction range satisfying printability.

A method of detecting six ridge lines connecting R, G, and B and K, respectively, and connecting C, M, and Y and W, respectively, will be explained with a ridge line connecting R and K cited as an example.

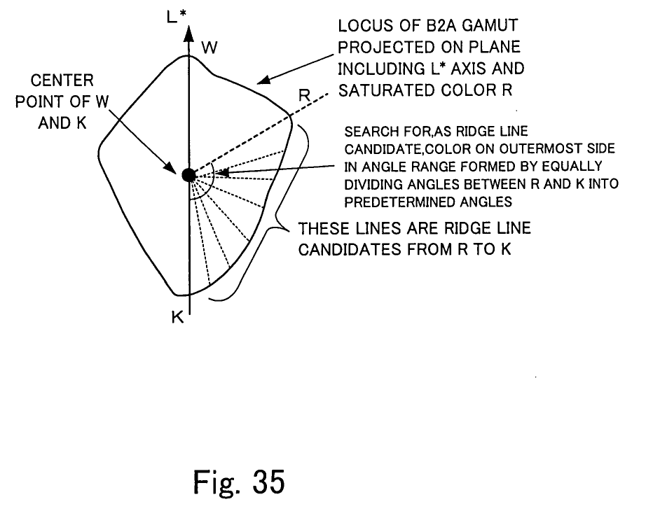

FIG. 35 is an explanatory diagram of a method of detecting a ridge line connecting R and K. The printable color reproduction range obtained in the color-reproduction-range calculating step in step (a1) in FIG. 6 (the inverse conversion step (step (a11) and the adaptive conversion step (step (a12)) in FIG. 7) is projected on a plane including the L* axis and the saturated color of R (the vertex of R). An outermost edge line connecting R and K of a two-dimensional color reproduction range obtained by the projection is detected as a ridge line connecting R and K. Hues of respective colors on this outermost edge line are not fixed. If a three-dimensional printable color reproduction range is sliced along a plane including the L* axis and the saturated color of R, the outermost edge line connecting R and K has a fixed hue on a two-dimensional color reproduction range as a section obtained by the slicing. However, since the three-dimensional printable color reproduction range is projected on the two-dimensional plane, an outermost edge line in the two-dimensional color reproduction range obtained by the projection does not have a fixed hue on the three-dimensional printable color reproduction range.

In calculating the outermost edge line, as shown in FIG. 35, color points on the most outer side are detected for respective predetermined angle ranges with a midpoint of W and K on the L* axis set as the center and the color points are set as color points on the ridge line. However, since filtering processing described later is not performed, the color points detected in this way and ridge lines connecting the color points are only candidates of color points and ridge lines at this point.

A method of detecting ridge lines connecting G and B and K, respectively, and a method of detecting ridge lines connecting C, M, and Y and W, respectively, are the same as the method of detecting a ridge line connecting R and K.

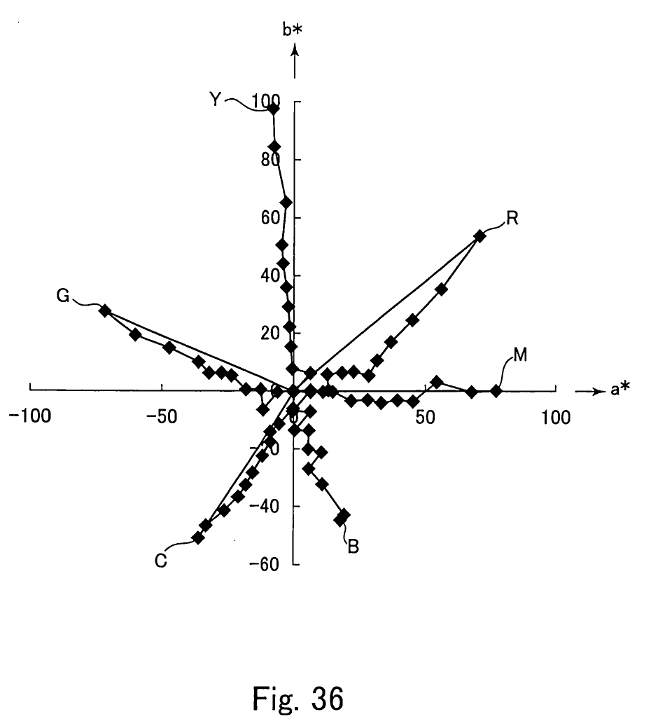

FIG. 36 is a diagram showing six ridge lines connecting R, G, and B and K, respectively, and connecting C, M, and Y and W, respectively, detected by the method.

As it is seen from FIG. 36, deviation of a hue due to misdetection is observed in places.

Thus, noise reduction processing described below is applied to the six ridge lines once detected as described above.

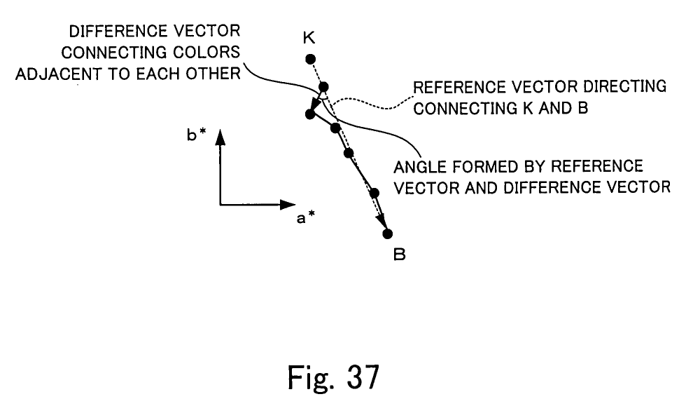

FIG. 37 is a schematic diagram showing noise reduction processing applied to the ridge line connecting B and K. Although the ridge line connecting B and K is explained here, the same holds true for the ridge lines connecting R and G and K, respectively, and the ridge lines connecting C, M, and Y and W, respectively.

Here, a reference vector directly connecting K and B and a difference vector connecting adjacent color points among color points forming the ridge line connecting K and B are calculated. An angle formed by the reference vector and the difference vector is calculated. When the angle formed by the reference vector and the difference vector is equal to or larger than a predetermined angle (here, 30 degrees), it is judged that the color points are noise and the color points are discarded from the ridge line.

In this way, the three ridge lines connecting R, G, and B and K, respectively, and the three ridge lines connecting C, M, and Y and W, respectively, are calculated. When put together with the six ridge lines connecting R and Y, Y and G, G and C, C and B, B and M, and M and R described above, twelve ridge lines in total are calculated. As described above, saturated colors (vertices) of W, K, R, G, B, C, M and Y are calculated.

The processing described above is processing of the vertex-and-ridge-line detecting step (step (a21)) shown in FIG. 8 in the virtual-profile creating step (step (a2)) shown in FIG. 6.

The ridge-line-profile creating step in step (a22) shown in FIG. 8 will be explained.

In this ridge-line-profile creating step, plural points are set at equal intervals on respective ridge lines on a dummy RGB color space and a ridge line profile associating coordinate points (RGB values) in the dummy RGB color space concerning the respective ridge lines with coordinate points (L*a*b* values) in the L*a*b* color space is created such that, when the plural points are mapped onto the L*a*b* color space, the plural points arranged at equal intervals on the respective ridge lines on the dummy RGB color space are arranged at equal intervals on the respective ridge lines calculated as described above in the L*a*b* color space as well. However, intervals of the plural points on the respective ridge lines only have to be equal in the respective ridge lines and the intervals may be different for each of the ridge lines.

In this embodiment, a ridge line profile is calculated such that eighteen ridge line lattice points including the two vertices at both ends of the respective ridge lines are arranged at equal intervals on the respective ridge lines on the dummy RGB color space and the eighteen ridge line lattice points are arranged at equal intervals on the corresponding ridge lines calculated as described above on the L*a*b* color space as well.

The number of color points on the respective ridge lines of the L*a*b* color space is less than eighteen because the color points of noise are removed by the various kinds of filtering processing. Thus, first, colors are supplemented to increase the number of color points on the respective ridge lines to eighteen.

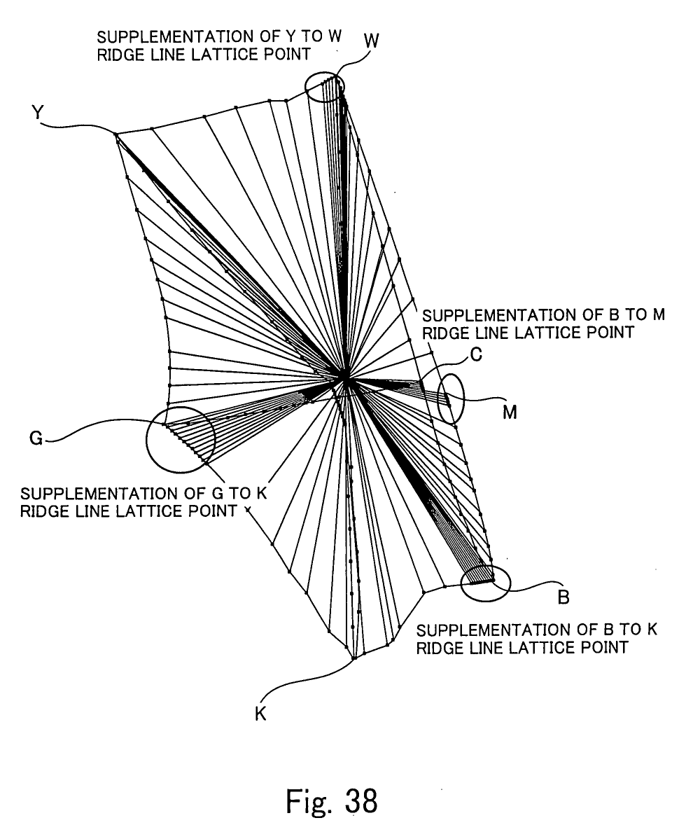

FIG. 38 is a diagram showing a state in which color points are supplemented to increase the number of color points on the respective ridge lines in the L*a*b* color space to eighteen.

Concerning the respective ridge lines connecting the R, G, and B and K, the respective saturated colors of R, G, and B and color points on ridge lines closest to the saturated colors are connected by straight lines and color points in a number short of eighteen are supplemented on the straight lines. Concerning the respective ridge lines connecting C, M, and Y and W, a vertex of W and color points on a ridge line closest to W are connected by a straight line and color points in a number short of eighteen are supplemented on the straight line. Moreover, concerning the six ridge lines connecting R-Y-G-C-B-M-R in order, color points in a number short of eighteen are supplemented on straight lines connecting one saturated color of saturated colors at both ends of the respective ridge lines and color points on a ridge line closest to the saturated color.

As described above, the number of lattice points on the respective ridge lines in the dummy RGB color space and the number of color points on the respective ridge lines on the L*a*b* color space are set to the same number of eighteen. Then, equal interval processing according to an algorithm described below is performed.

(a) Concerning one ridge line, a color difference ΔE_neighbor, i (i=1 to 17) between adjacent lattice points on the ridge line is calculated.

(b) An accumulated color difference string ΔE_ruiseki, i (i=0 to 17) from one end of the one ridge line is calculated.

ΔE_ruisekiᵢ=Σⱼ₌₀^{j=i}(ΔE_neighborⱼ) [Formula 1]

(c) A one-dimensional Look-Up Table (1DLUT) with respective accumulated color differences ΔE_ruiseki, i (i=0 to 17) set as inputs and L* values of respective lattice points on the one ridge line set as outputs is created.

(d) Concerning a* values and b* values, in the same manner, respective 1DLUTs with respective accumulated color differences ΔE_ruiseki, i (i=0 to 17) set as inputs and a* values and b* values of respective lattice points on the one ridge line set as outputs, respectively, are created and 1DLUT×3 for L*, a*, and b* corresponding to the accumulated color differences ΔE_ruiseki, i (i=0 to 17) are created.

(e) Output values L*, a*, and b* at the time when a value ΔE_ruiseki, 17×i/17 (i=0 to 17) is inputted to the 1DLUT×3 are set as new color points on the one ridge line.

(f) The arithmetic processing is performed for the respective ridge lines.

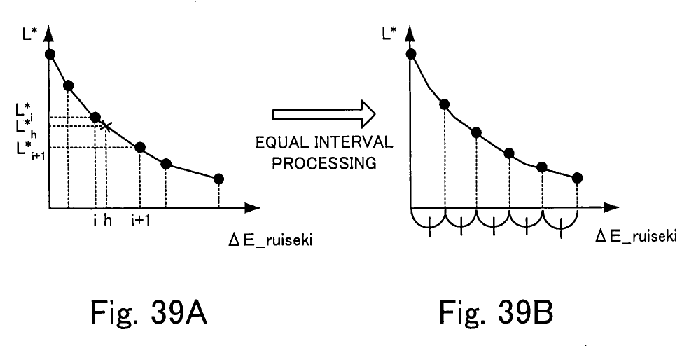

FIGS. 39A and 39B are explanatory diagrams of equal interval processing employing the 1DLUT that is inputted with an accumulated color difference and outputs an L* value in (e) above.

In this 1DLUT, a correspondence relation between ΔE_ruiseki and the L* value for the respective points indicated by black circles in FIG. 39A is described.

In calculating, for example, an L* value (L*ₕ) corresponding to ΔE_ruiseki at an h point using this 1DLUT, L* values (Lᵢ*Lᵢ₊₁*) of two points (here, i point and i+1 point) on the 1 DLUT on both sides of the h point are read out and the L*values are linearly interpolated to calculate L*h.

According to such an interpolation operation, L* values of respective points arranged at equal intervals on an axis of ΔE_ruiseki shown in FIG. 39B are calculated. The same arithmetic processing is performed for the a* values and the b* values.

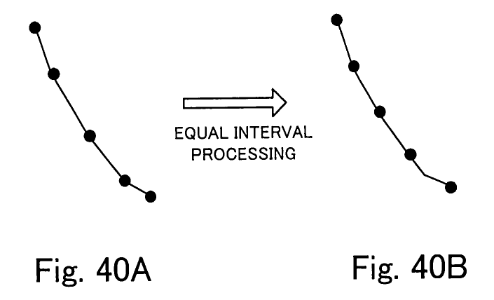

FIGS. 40A and 40B are conceptual diagrams of lattice points on a ridge line before and after the equal interval processing.

Before the equal interval processing, as shown in FIG. 40A, lattice points are arranged at unequal intervals on one ridge line. When the equal interval processing is applied to the lattice points, as shown in FIG. 40B, lattice points arranged at equal intervals are arrayed on the one ridge line in a distance along the ridge line.

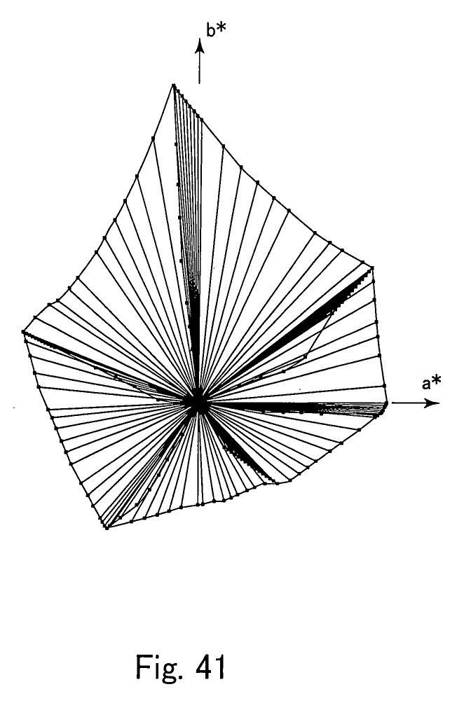

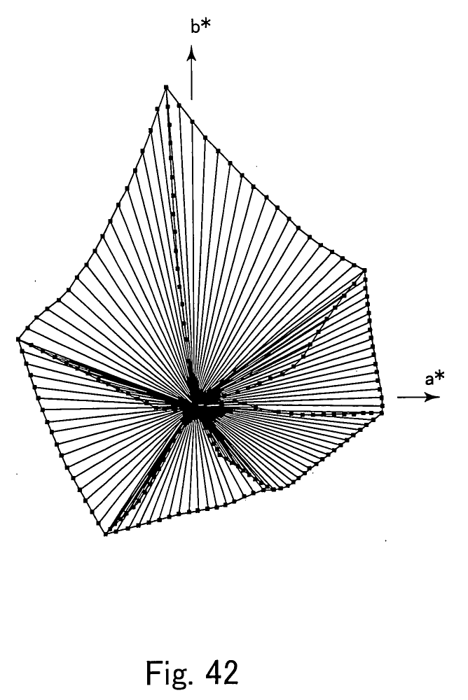

FIG. 41 is a diagram showing a color reproduction range before the equal interval processing. FIG. 42 is a diagram showing a color reproduction range after the equal interval processing.

In FIG. 41, plural color points supplemented on a straight line connecting a saturated color and color points closest to the saturated color are densely arranged and intervals of the color points on ridge lines are irregular. However, in FIG. 42, although intervals are different for the respective ridge lines, plural color points are arranged at equal intervals on the respective ridge lines. These color points correspond to plural lattice points arranged at equal intervals on corresponding ridge lines on a dummy RGB color space in a one-to-one relation.

The processing described above is processing in the ridge-line-profile creating step in step (s22) shown in FIG. 8.

The gray-axis-profile creating step in step (a23) in FIG. 8 will be explained.

Here, a gray-axis profile concerning the gray axis of the color reproduction range of the virtual printer 14 associating coordinate points on a dummy RGB color space with coordinate points on an L*a*b* color space is created such that, when plural points are set at equal intervals on the gray axis connecting the two vertices of W and K in the color reproduction range of the virtual printer 14 in the dummy RGB color space and the plural points are mapped onto an L*a*b* color space, the plural points mapped onto the L*a*b* color space are arranged at equal intervals on the gray axis connecting the vertex in step (a21) in FIG. 8 and the two vertices of W and K on the L*a*b* color space detected in the ridge-line detecting step.

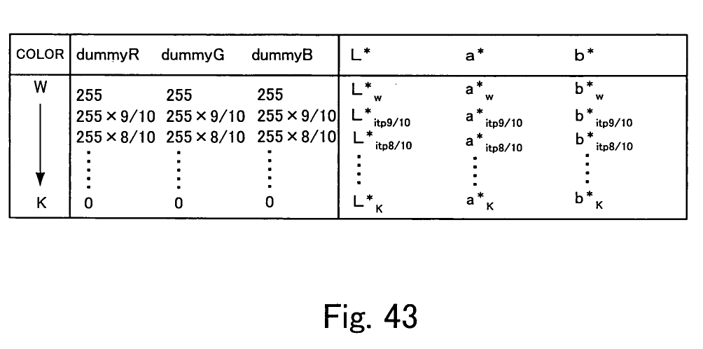

FIG. 43 is a diagram showing a table representing a gray axis profile.

Here, a vertex of W, (R, G, B)=(255, 255, 255), is associated with a W point (L*, a*, b*)=(L*_{w}a*_{w}b*_{w}) on L*a*b*. A vertex of K, (R, G, B)=(0, 0, 0), is associated with a K point (L*, a*, b*)=(L*ₖa*ₖb*ₖ) on L*a*b*. Plural points (R, G, B)=(255, 255, 255), (255×( 9/10), 255×( 9/10)), 255×(9/10), . . . , and (0, 0, 0) set at equal intervals on a gray axis connecting W and K on a dummy RGB color space are associated with respective points (L*, a*, b*)=(L*_{w}a*_{w}b*_{w}), (L*_{itp9/10}a*_{itp9/10}b*_{itp9/10}), (L*_{itp8/10}a*_{itp8/10}b*_{itp8/10}), . . . , and (L*ka*kb*k) arranged at equal intervals on a gray axis connecting W and K on an L*a*b* color space. L*_{itp9/10} and the like indicate the following.

$${L}_{itpi / 10}^{*} = {L}_{w}^{*} \times i / 10 + {L}_{k}^{*} ( 10 - i ) / 10$$

$${a}_{itpi / 10}^{*} = {a}_{w}^{*} \times i / 10 + {a}_{k}^{*} \times ( 10 - i ) / 10$$

$${b}_{itpi / 10}^{*} = {b}_{w}^{*} \times i / 10 + {b}_{k}^{*} \times ( 10 - i ) / 10$$

The equal interval points on the gray axis of the dummy RGB color space are associated to be arranged at equal intervals on the gray axis of the L*a*b* color space is to realize gamut mapping without gray level distortion.

In FIG. 43, the dummy RGB and the L*a*b* are associated for respective points obtained by equally dividing the gray axis into ten. However, this is for convenience of illustration and explanation. It is unnecessary to divide the gray axis into ten. The dummy RGB and the L*a*b* may be associated for a larger number of points.

The above processing is processing in the gray-axis-profile creating step in step (a23).

The interpolation operation step in step (a24) in FIG. 8 will be explained.

Here, according to an interpolation operation with the twelve ridge line profiles created in the ridge-line-profile creating step in step (a22) in FIG. 8 and the gray axis profile created in the gray-axis-profile creating step in step (a23) in FIG. 8 set as boundary conditions, coordinate points on a dummy RGB color space and coordinate points on an L*a*b* color space are associated for the entire dummy RGB color space dependent on the virtual printer 14. Consequently, a virtual profile associating the dummy RGB color space with the L*a*b* color space is created. An interpolation operation employing the method of sectional polynomial approximation described in Japanese Patent Application Laid-Open No. 2004-266590 is adopted.

For each of L*a*b*, the following quadratics are used.

L*=a₀R²+a₁G²+a₂B²+a₃RG+a₄GB+a₅BR+a₆R+a₇G+ₐ₈B+a₉

a*=b₀R²+b₁G²+BB²+b₃RG+b₄GB+b₅BR+b₆R+b₇G+b₈B+b₉

b*=c₀R²+c₁G²+c₂B²+c₃RG+c₄GB+c₅BR+c₆R+c₇G+c₈B+c₉

With points in which the dummy RGB values and the L*a*b* values of the ridge line profile and the gray axis profile created as described above are associated are set as sample points, respective coefficients a₀ to a₉, b₀ to b₉, and c₀ to c₉ are calculated. The respective coefficients calculated are substituted in the above quadratics. Association of the dummy RGB values with the L*a*b* values is performed for the entire color reproduction range of the printer 14.

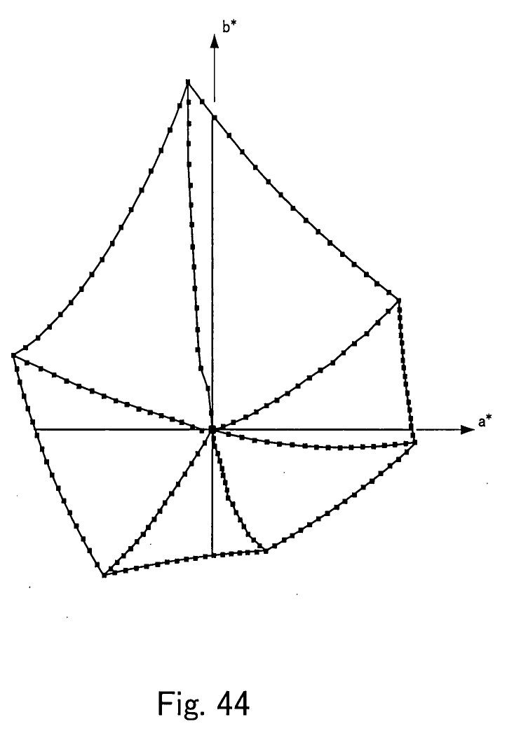

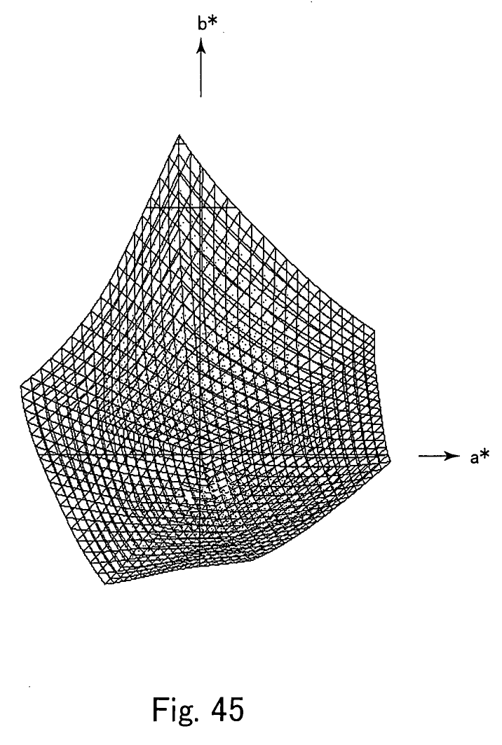

FIG. 44 is a diagram showing a profile associating dummy RGB and L*a*b* before the interpolation operation processing (only ridge lines and a gray axis are associated). FIG. 45 is a profile (a dummy RGB gamut) associating dummy RGB with L*a*b* after the above interpolation operation processing.

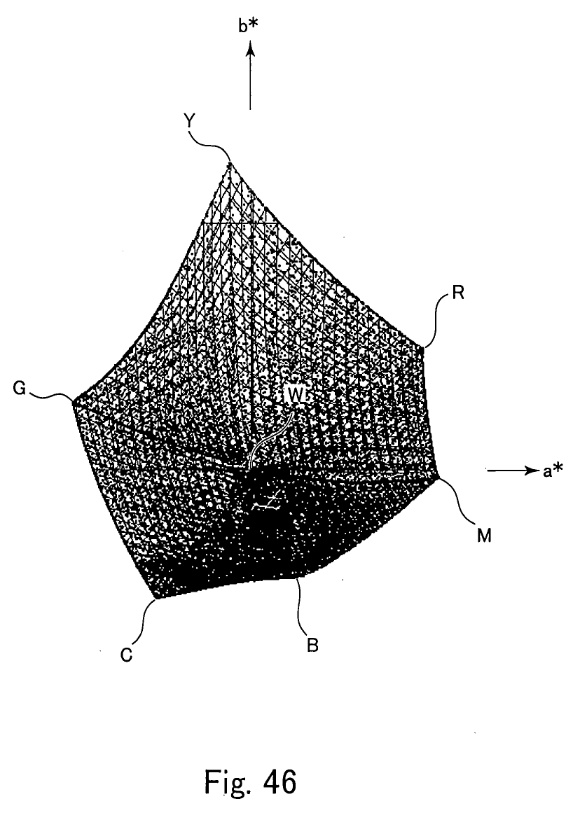

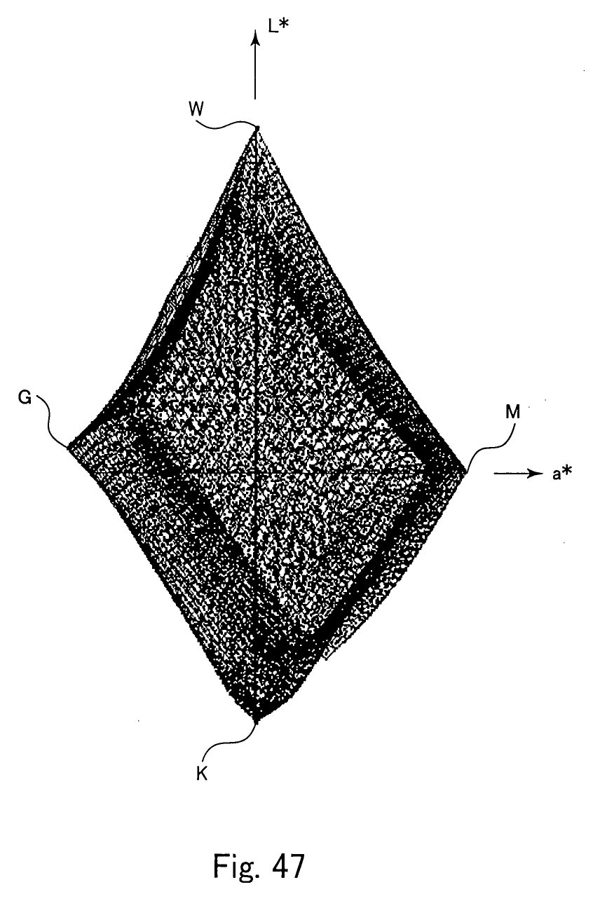

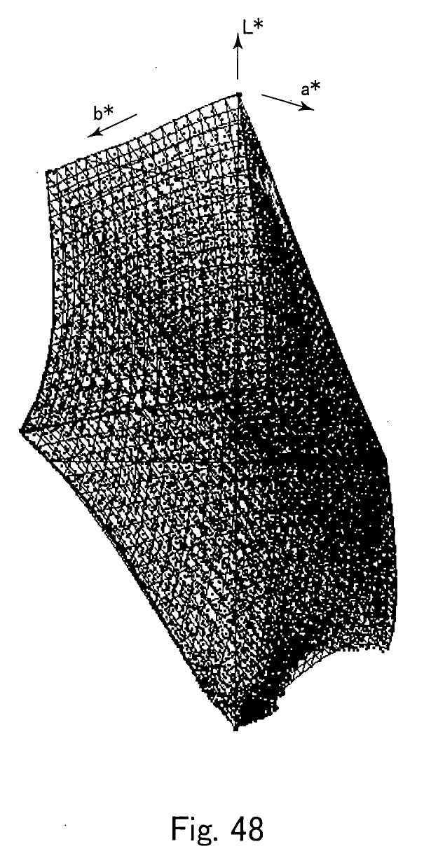

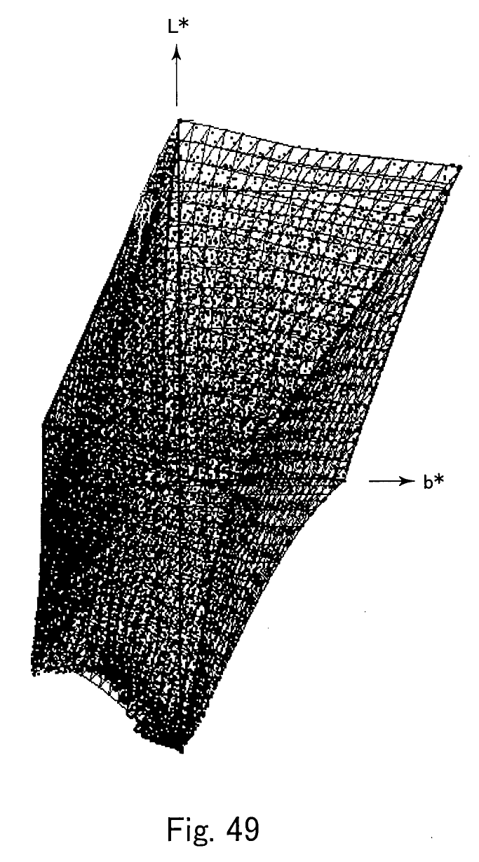

FIGS. 46 to 49 each show a diagram of a dummy RGB gamut (mesh) calculated by the above interpolation operation processing and a printable color reproduction range (B2A1 gamut) (dots) calculated in the color-reproduction-range calculating step (step (a1)) in FIG. 6 in a state in which the dummy RGB gamut and the printable color reproduction range are overlapped and viewed from various angles.

As shown in FIGS. 46 to 49, it is seen that, according to the arithmetic processing explained, saturated color (vertices) and ridge lines are detected appropriately and the dummy RGB gamut substantially coinciding with the B2A1 gamut is obtained.

The processing explained above is processing in the interpolation operation step in step (a24) in FIG. 8.

The first link-profile creating step (step (B)) in FIG. 5 will be explained.

In the first link-profile creating step (step (B) in FIG. 5), a link profile for converting a dummy RGB color space into a CMYK color space is calculated using the virtual profile (the dummy RGB gamut) connecting the dummy RGB color space and the L*a*b* color space created in the virtual-profile creating step (step (a2)) in FIG. 6 including the vertex-and-ridge-line detecting step (step (a21)), the ridge-line-profile creating step (step a22)), the gray-profile creating step (step (a23)), and the interpolation operation step (step (a24)) in FIG. 8 and the inverse conversion profile (the B2A1 profile) (see FIG. 15) having the printable color reproduction range calculated in the color-reproduction-range calculating step in step (a2) in FIG. 6 (the adaptive conversion step (step (a11) and the inverse conversion step (step (a12)) in FIG. 7) (see FIG. 17).

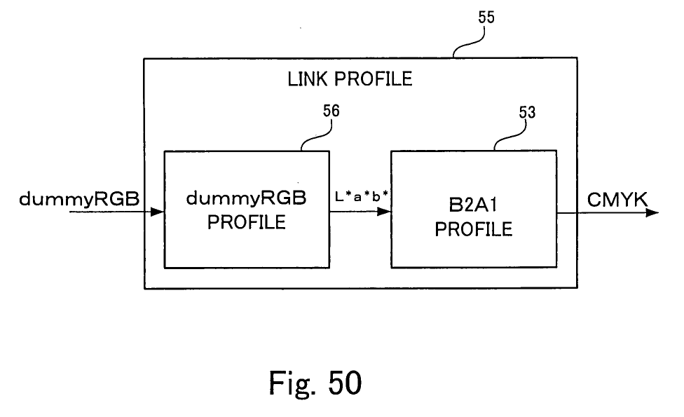

FIG. 50 is a conceptual diagram of a method of calculating a link profile.

A lattice point (a dummy RGB value) on a dummy RGB color space is converted into a coordinate (an L*a*b* value) on an L*a*b* color space by the dummy RGB profile 56. The L*a*b* value is converted into a coordinate (a CMYK value) on a CMYK color space by the B2A1 profile 53.

The second link-profile creating step (step (C)) of the color conversion definition creating method shown in FIG. 5 will be explained. Here, the method disclosed in Japanese Patent Application Laid-Open No. 2001-103329 will be explained.

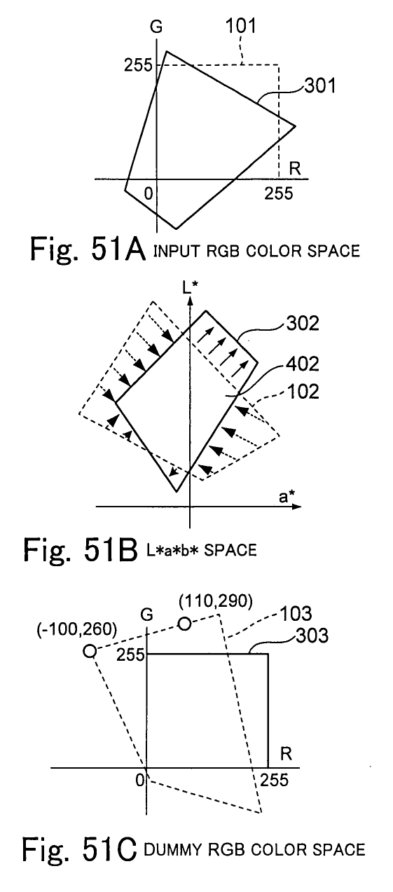

FIGS. 51A to 51C are schematic diagrams of color reproduction ranges of the printer 11 and the virtual printer 14 shown in FIG. 2.

FIG. 51A is a diagram showing an input RGB color space dependent on the printer 11. In FIG. 51A, an R-G plane is shown for simplification of illustration. FIGS. 51B and 51C are the same. In FIG. 51B, an L*-a* plane of an L*a*b* space, which is one of a common color space, is shown. In FIG. 51C, an R-G plane of a dummy RGB color space dependent on the virtual printer 14 is shown.

The printer 11 print-outputs the print image 11a on the basis of image data representing numerical values 0 to 255 for R, G, and B. In this case, a color reproduction range of the printer 11 is a rectangular range 101 shown in FIG. 51A.

When the color reproduction range 101 of the printer 11 shown in FIG. 51A is mapped to the L*a*b* space with reference to the color reproducibility (the printer profile 51) of the printer 11, the color reproduction range of the printer 11 is represented as indicated by a range 102. When the color reproduction range is further mapped to the dummy RGB color space dependent on the virtual printer 14 with reference to the color reproducibility (the virtual profile 53 (see FIG. 16)) of the virtual printer 14 created as described above, the color reproduction range of the printer 11 is represented as indicated by a range 103 shown in FIG. 51C.

On the other hand, the color reproduction range (the virtual profile) of the virtual printer 14 shown in FIG. 2 is a cubic range (in FIG. 51C, a rectangular range 303 on the R-G plane) indicated by a numerical value range of 0 to 255 of R, G, and B on the dummy RGB color space in FIG. 51C. In other words, when image data representing coordinate points in the numerical value range of 0 to 255 for R, G, and B in an input RGB space dependent on the printer 11 is converted into image data on the dummy RGB color space through the L*a*b* space, the image data may be converted into a value exceeding colors (in a range of 0 to 255 of R, G, and B on the image data) that can be represented by the virtual printer 14, for example, (R, G)=(110, 290), (R, G)=(−100, 260), or the like shown in FIG. 51C. In that case, these image data, i.e., image data deviating from the color reproduction range of the virtual printer 14 cannot be outputted by the virtual printer 14. Thus, it has been conventionally proposed to clip the image data so as to be image data located in a boundary of the color reproduction range of the virtual printer 14. Specifically, (R, G)=(110, 290) is changed to (R, G)=(110, 255) and (R, G)=(−100, 260) is changed to (R, G)=(0, 255).

In the case of mapping in a color space dependent on a converted side (the virtual printer 14), a degree of freedom of the mapping is small. The mapping for simply clipping data deviating from the color reproduction range of the virtual printer 14 described above and moving the data to a boundary of the color reproduction range is performed. In mapping data from a color reproduction range of one device (e.g., the printer 11) to a color reproduction range of another device (e.g., the virtual printer 14), in particular, accuracy of mapping near boundaries of the color reproduction ranges may substantially fall.

On the other hand, when a color reproduction range 303 of the virtual printer 14 indicated by a rectangular range of 0 to 255 in FIG. 51C is mapped to the L*a*b* space using the color reproducibility (the virtual profile) of the virtual printer 14, the color reproduction range is represented as indicated by a range 302 in FIG. 51B. Several methods have been conventionally proposed to convert data in the color reproduction range 102 of the printer 11 (the first device) into data in the color reproduction range 302 of the virtual printer 14 (the second device) in a common color space represented by the L*a*b* space.

In the color conversion (mapping) in the L*a*b* space, when it is attempted to use a color reproduction range, which can be represented by the virtual printer 14, as wide as possible, in general, both “compression” for mapping data deviating from a common range 402 of the color reproduction range 101 of the printer 11 and the color reproduction range 302 of the virtual printer 14 to the inside of the common range 402 as indicated by an arrow of a broken line in FIG. 51B and “expansion” for expanding data in the common range 402 to the outside of the common range 402 while keeping a condition of inside of the color reproduction range 302 of the virtual printer 14 as indicated by an arrow of a solid line in FIG. 50B are performed.

In the mapping in the common color space represented by the L*a*b* conventionally proposed, since a degree of freedom of the mapping is too large, it is highly likely that tones are discontinuous or an image of an unnatural impression is obtained.

When the color reproduction range of the virtual printer 14 mapped to the L*a*b* space in FIG. 51B is further mapped to the input RGB color space in FIG. 50A, the color reproduction range 302 is represented as indicated by a range 301 of a “distorted” shape having a portion sticking out from the rectangular range 101, which is the color reproduction range of the printer 11.

The common color space will be explained. The L*a*b* color space is explained as an example of the common color space. However, the common color space does not have to be the L*a*b* color space but only has to be a color space defined not to depend on a specific input device or a specific output device. For example, the common color space may be an XYZ color space other than the L*a*b* color space or may be a coordinate system clearly defined such that respective coordinate points on a color space are associated in a one-to-one relation. As an example of such a coordinate system, there is a standard RGB signal defined as follows.

$$[ \begin{matrix}{R}_{sRGB} \\ {G}_{sRGB} \\ {B}_{sRGB}\end{matrix} ] = [ \begin{matrix}3.2410 & - 1.5374 & - 0.4986 \\ - 0.9692 & 1.8760 & 0.0416 \\ 0.0556 & - 0.2040 & 1.0570\end{matrix} ] [ \begin{matrix}X \\ Y \\ Z\end{matrix} ] \qquad [ Formula 2 ]$$

Here, for example, R_{SRGB} represented by 8 bits is described in R_{8bit} as follows.

R_{8bit}=255×12.92R_{SRGB} (0<R_{SRGB}<0.00304)

R_{8bit}=255×1.055R_{SRGB}(1.0/2.4)−0.055 (0.00304≦R_{SRGB}≦1)

### G_{8bit} and B_{8bit} representing G_{SRGB} and B_{SRGB} in 8 bits can be converted from G_{SRGB} and B_{SRGB}, respectively, in the same manner.

Alternatively, a color space defined by CMY density of a reversal film may be adopted as the common color space. When the common color space is decided, a color reproduction range in the common color space is clearly defined.

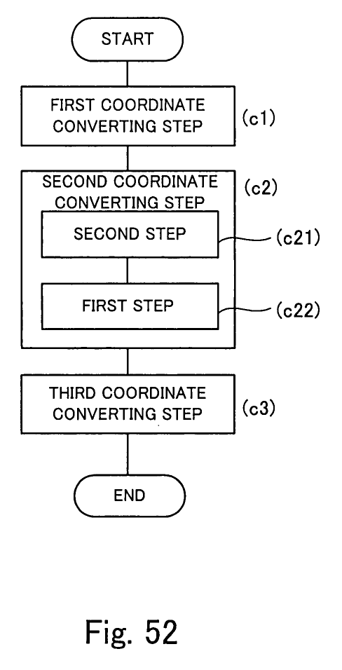

FIG. 52 is a flowchart showing the second link-profile creating step of the color conversion definition creating method according to the color conversion definition creating program executed in the computer system shown in FIGS. 2 and 3. FIG. 52 as a whole is equivalent to the second link-profile creating step in step (C) in FIG. 5.

The second link profile in the invention is created through a first coordinate converting step (step c1), a second coordinate converting step (step c2), and a third coordinate converting step (step c3). In the second coordinate converting step (step c2), basically, a first step (step c22) is executed. However, in this embodiment, a second step (step c21) is provided at a pre-stage of the first step to create a more highly accurate color conversion definition.

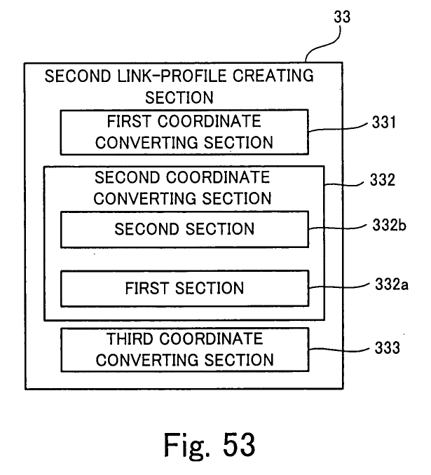

FIG. 53 is a diagram showing the second link-profile creating section 33 (see FIG. 9) of the color conversion definition creating program executed in the computer system shown in FIGS. 3 and 4.

The second link-profile creating section 33 includes a first coordinate converting section 331, a second coordinate converting section 332, and a third coordinate converting section 333. The second coordinate converting section 332 includes a first section 332a and a second section 332b executed at a pre-stage of the first section 332a.

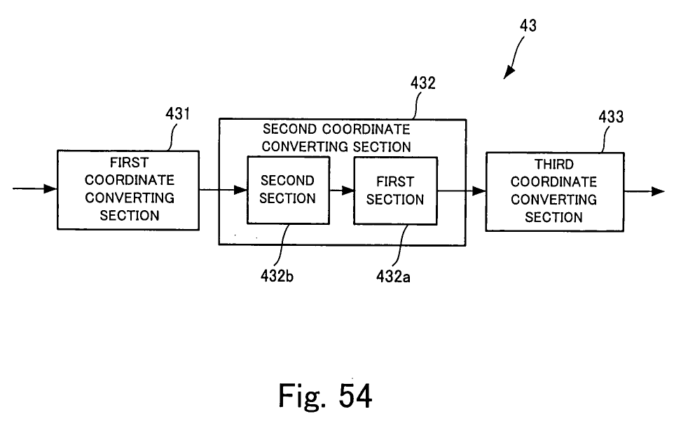

FIG. 54 is a functional block diagram of the second link-profile creating section 42 (see FIG. 11) of the color conversion definition creating apparatus 40 established in the computer 20 when the color conversion definition creating program is executed in the computer 20 shown in FIGS. 3 and 4.

The second link-profile creating section 42 includes a first coordinate converting section 431, a second coordinate converting section 432, and a third coordinate converting section 433. The second coordinate converting section 432 includes a first section 432a and a second section 432b arranged at a pre-stage of the first section 432a.

The steps c1, c2 (c21 and c22), and c3 of the second link-profile creating step of the color conversion definition creating method shown in FIG. 52 correspond to the sections 331, 332 (332b and 332a), and 333 forming the second link-profile creating section shown in FIG. 53, respectively, and corresponds to the sections 431, 432 (432b and 432a), and 433 forming the second link-profile creating section 43 shown in FIG. 54, respectively. In the following description, the steps c1, c2 (c21 and c22), and c3 of the second link-profile creating step in FIG. 52 are explained as an example to cover explanations of the sections 331, 332 (332b and 332a), and 333 of the second link-profile creating section 33 in FIG. 53 and the sections 431, 432 (432b and 432a), and 433 of the second link-profile creating section 43 in FIG. 54.

Steps (step c1, c2 (c21 and c22), and c3) forming a first color-conversion-definition creating step shown in FIG. 52 will be sequentially explained.

First, in a coordinate converting step in step c1 in FIG. 52, color reproducibility (a printer profile) of the printer 11 is referred to and respective coordinate points (coordinate points on respective lattices set discretely) in the input RGB color space dependent on the printer 11 are mapped to a common color space (e.g., an L*a*b* space) that does not depend on a device.

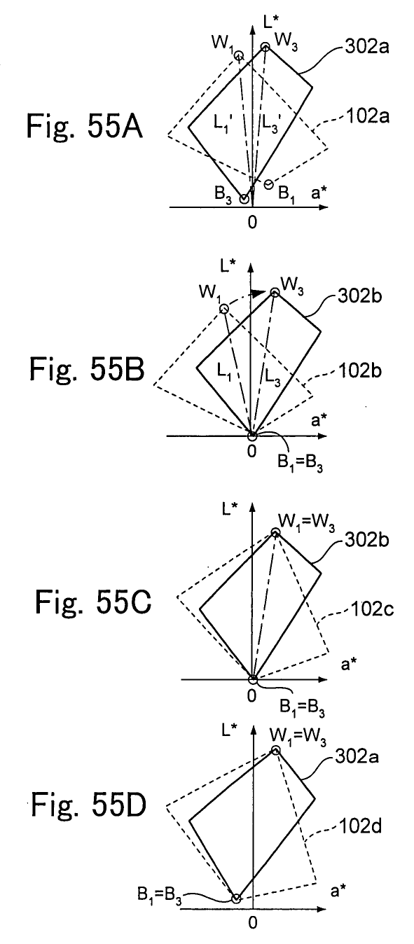

FIGS. 55A to 55D are explanatory diagrams of the second step (step c21) in the second coordinate converting step executed in step c2 in FIG. 52. FIGS. 55A to 55D show a color reproduction range of the printer 11 and a color reproduction range of the virtual printer 14 in the L*a*b* space.

Here, adaptive conversion to which the Von Kries conversion is applied is performed. Coordinate conversion is performed such that a coordinate point W₁ equivalent to white (a color of a sheet of the print image 11a) represented by the print image 11a (see FIG. 2) print-outputted by the printer 11 and a coordinate point B₁ equivalent to black (a state in which printing is performed in the printer 11 using a maximum quantity of inks of the colors R, G, and B) that can be represented as the print image 11a coincide with a coordinate point W₃ equivalent to white of an image (a color of a sheet of the image) virtually outputted by the virtual printer 14 and a coordinate point B₃ equivalent to black (a color printed using a maximum quantity of inks of the colors R, G, and B by the virtual printer 14), respectively.

FIGS. 55A to 55D show this coordinate converting step. First, a color reproduction range 102a of the printer 11 and a color reproduction range 302a of the virtual printer 14 shown in FIG. 55A are translated such that black points B₁ and B₃ coincide with an origin 0 (a theoretical black point) as shown in FIG. 55B. Consequently, first, a black point of the color reproduction range 102b of the printer 11 and a black point of the color reproduction range 302b of the virtual printer 14 coincide with each other.

Subsequently, coordinate conversion involving rotation and stretch is applied to the entire color reproduction range 102b of the printer 11 such that a white point W₁ of a color reproduction range 102b of the printer 11 after the translation coincides with the white point W₃ of a color reproduction range 302b of the virtual printer 14, i.e., a straight line L₁ coincides with a straight line L₃ in FIG. 55B.

FIG. 55C shows a state after the coordinate conversion involving rotation and stretch is performed. The color reproduction range of the printer 11 is converted from the color reproduction range 102b shown in FIG. 55B to the color reproduction range 102c shown in FIG. 55C. In this case, the white point W₁ of the color reproduction range of the printer 11 coincides with the white point W₃ of the color reproduction range of the virtual printer 14.

Thereafter, as shown in FIG. 55D, the color reproduction range 102c of the printer 11 in which the white points and the black points coincide with each other, respectively, as shown in FIG. 55C is translated to the original reproduction range of the virtual printer 14, i.e., a position coinciding with the white point W₃ and the black point B₃ of the color reproduction range 302a of the virtual printer 14 shown in FIG. 55A.

Consequently, it is possible to obtain the color reproduction range 102d of the printer 11 in which the white point W₁ and the black point B₁ coincide with the white point W₃ and the black point B₃ of the virtual printer 14, respectively.

The operation described above is represented by formulas as follows. In FIG. 55, the color reproduction range in the L*a*b* space is shown. However, the Von Kries conversion and the adaptive conversion to which the Von Kries conversion is applied are often executed in an XYZ space. Thus, in the following explanation, the XYZ space is assumed. The XYZ space is one of a common color space in which coordinate points thereof correspond to coordinate points of the L*a*b* space in a one to one relation.

When XYZ coordinates of the white point W₁ and the black point B₁ of the color reproduction range 102a of the printer 11 shown in FIG. 55A are set as (LXW₁, LYW₁, LZW₁) and (LXB₁, LYB₁, LZB₁), respectively, and XYZ coordinates of the white point W₃ and the black point B₃ of the color reproduction range 302a of the virtual printer 14 shown in FIG. 55A are set as (LXW₃, LYW₃, LZW₃) and (LXB₃, LYB₃, LZB₃), respectively, XYZ coordinates (LXW₁′, LYW₁′, LZW₁′) and (LXW₃′, LYW₃′, LXW₃′) equivalent to the white points W₁ and W₃ shown in FIG. 55B are calculated by the following formulas.

LXW₁′=LXW₁−LXB₁

LYW₁′=LYW₁−LYB₁

LZW₁′=LZW₁−LZB₁ (1)

LXW₃′=LXW₃−LXB₃

LYW₃′=LYW₃−LYB₃

LZW₃′=LZW₃−LZB₃ (2)

### A Von Kries matrix for performing rotation and stretch such that the white point W₁ (LXW₁′, LYW₁′, LZW₁′) coincides with the white point W₃ (LXW₃′, LYW₃′, LZW₃′) is created.

This Von Kries matrix is described as follows.

VK=[MTX_{VK}] (3)

### This Von Kries matrix is a 3×3 matrix.

Subsequently, the coordinate points in the input RGB space dependent on the printer 11 is mapped to the L*a*b* space in step c1 in FIG. 52. A large number of coordinate points further converted into the XYZ space (or directly mapped from the input RGB color space dependent on the printer 11 to the XYZ space) are represented as (X, Y, Z). This (X, Y, Z) is subjected to black point correction (see FIG. 55B) according to the following formulas.

X₁=X−LXB₁

Y₁=Y−LYB₁

Z₁=Z−LZB₁ (4)

### Subsequently, the Von Kries conversion is performed according to the following formula (see FIG. 55C).

$$\begin{matrix}\text{[Formula 3]} & \\ ( \begin{matrix}X 2 \\ Y 2 \\ Z 2\end{matrix} ) = ( {MTX}_{VK} ) ( \begin{matrix}X 1 \\ Y 1 \\ Z 1\end{matrix} ) & ( 5 )\end{matrix}$$

### Subsequently, correction for moving the black point to coincide with the black point of the virtual printer 14 (see FIG. 54D) is performed according to the following formulas.

X′=X2−LXB3

Y′=Y2−LYB3

Z′=Z2−LZB3 (6)

By applying the arithmetic operations to all the coordinate points, the color reproduction range 102a of the printer 11 shown in FIG. 55A represented in the L*a*b* space is converted into the color reproduction range 102d shown in FIG. 55D in which the white point and the black point coincide with the white point and the black point of the color reproduction range 302a of the virtual printer 14.

When the adaptive conversion is performed in the XYZ space, the coordinate (X, Y, Z) of the black points before the adaptive conversion (the black points B1 and B3 in FIG. 55A) is substantially (0, 0, 0). Therefore, it is advantageous in that numerical values are slightly changed for correction of the black points, an amount of movement is small even if the coordinates of the white points are moved in accordance with Formulas (1) and (2), and it is possible to perform adaptive change using a wide range in the XYZ space. However, this adaptive change does not always have to be performed in the XYZ space and may be performed in the L*a*b* space or may be performed in other common color spaces.

The adaptive conversion for making both the white points and the black points coincide with each other, respectively, is explained above. However, although accuracy of color conversion falls more or less, as a simplified form, adaptive conversion may be performed to make only the white points coincide with each other without taking the black points into account.

When explained with reference to FIG. 54, this adaptive conversion for making only the white points coincide with each other means coordinate conversion shown in FIG. 55A with which the straight line L₁′ coincides with the straight line L₃′ and the white point W₁ coincides with the white point W₃. In terms of formula, the adaptive conversion means conversion for calculating, without subtracting a coordinate of the black point as in Formulas (1) and (2), a Von Kries matrix for performing rotation and stretch such the white point W₁ (LXW₁, LYW₁, LZW₁) coincides with the white point W₃ (LXW₃, LYW₃, LZW₃) and directly converting (X, Y, Z) using the Von Kries matrix without subtracting the coordinate of the black point as in Formula (4).

The adaptive conversion is necessary in the case of color conversion between devices having colors “white” substantially distant from each other calorimetrically, for example, when “white” on a CRT display screen is fairly bluish white and it is necessary to print-output an image displayed on the CRT display screen. However, the adaptive conversion, i.e., the second step (step c21) of the second coordinate converting step in FIG. 52, may be omitted when both the colors “white” substantially coincide with each other, for example, when the print image 11a print-outputted on a white sheet by the printer 11 and a proof image assumed to be print-outputted on the same white sheet by the virtual printer 14 are compared.

Next, the first step (step b22) in the second coordinate converting step of the flowchart shown in FIG. 52 will be explained citing several examples.

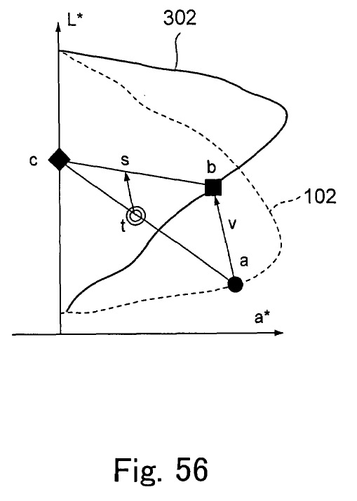

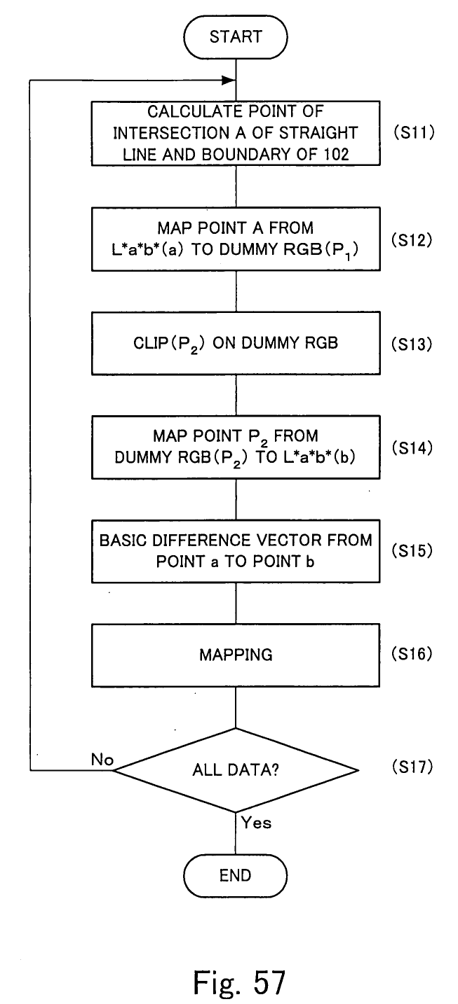

FIG. 56 is an explanatory diagram of a first example of the coordinate conversion in the first step. FIG. 57 is a flowchart of the first example. In FIG. 56, an L*-a* plane in an L*a*b* space is clearly shown. However, this is for convenience of illustration. Actually, three-dimensional coordinate conversion is performed in the L*a*b* space. The same holds true in various examples explained later.

First, a coordinate conversion reference coordinate point “c” forming a reference of the coordinate conversion is set. The coordinate conversion reference coordinate point “c” is set empirically or arbitrarily to some extent in accordance with a predetermined setting reference. However, the coordinate conversion reference coordinate point “c” is set in a common range of the color reproduction range 102 of the printer 11 and the color reproduction range 302 of the virtual printer 14 mapped to the L*a*b* space. Moreover, the coordinate conversion reference coordinate point “c” is set in the common range and, in this embodiment, on an L* axis (a gray axis). This is because, as it is seen from the following explanation, the coordinate conversion reference coordinate point “c” is not mapped to other coordinate points and, therefore, it is easy to keep a gray balance. For example, a point of (L*, a*, b*)=(50, 0, 0) is set as the coordinate conversion reference coordinate point “c”.

When the second coordinate converting step (step c2) of the flowchart in FIG. 52 includes the adaptive conversion (step c21) explained with reference to FIG. 55, the color reproduction range 102 of the printer 11 mapped to the L*a*b* space indicates a color reproduction range after the adaptive conversion.

A coordinate point in the color reproduction range 102 of the printer 11 on the L*a*b* space as an object of mapping is set as a first coordinate point “t”.

Assuming a straight line connecting the coordinate conversion reference coordinate point “c” and the first coordinate point “t”, a point of intersection of the straight line and a boundary of the color reproduction range 102 of the printer 11 is calculated (step S11 in FIG. 57). This point of intersection is referred to as a first reference coordinate point “a”.

The flowchart shown in FIG. 57 is a flowchart in the case in which the first reference coordinate point “a” calculated in this way deviates from the color reproduction range 302 of the virtual printer 14 mapped to the L*a*b* space as shown in FIG. 56. When this condition is satisfied, processing described below is further performed.

The first reference coordinate point “a” calculated as described above is mapped from the L*a*b* space to the dummy RGB color space dependent on the virtual printer 14 (step S12 in FIG. 57). A first reference coordinate point mapped to the dummy RGB color space is set as P₁.

Subsequently, in the dummy RGB color space, the first reference coordinate point P₁ is mapped onto the boundary of the color reproduction range of the virtual printer 14 of the dummy RGB color space by clipping a coordinate value of the first reference coordinate point P₁ (step S13). A point P₂ obtained on the boundary of the color reproduction range of the virtual printer 14 by this mapping is mapped from the dummy RGB color space to the L*a*b* space (step S14). A coordinate point mapped in the L*a*b* space is set as a second reference coordinate point “b” (see FIG. 56).

A basic difference vector “v” representing a difference between the first reference coordinate point “a” and the second reference coordinate point “b” shown in FIG. 56 and having the first reference coordinate point “a” as a start point and the second reference coordinate point “b” as an end point is calculated (step S15). The first coordinate point “t” which is about to be mapped is moved in a direction identical with a direction of the basic difference vector “v” onto a straight line connecting the coordinate conversion reference coordinate point “c” and the second reference coordinate point “b”. A point on the straight line to which the first coordinate point “t” is moved is set as a second coordinate point “s” to which the first coordinate point “t” is mapped (step S16).

Such coordinate conversion is applied to all coordinate points, the first reference coordinate point “a” calculated in step b1 of which is outside the color reproduction range 102 of the printer 11, among coordinate points included in the color reproduction range 102 of the printer 11 mapped to the L*a*b* space (step S17).

In this way, the coordinate conversion explained with reference to FIGS. 56 and 57 is performed, in determining a direction of the coordinate conversion, i.e., in calculating the basic difference vector “v”, by determining the second reference coordinate point “b” on the boundary of the color reproduction range of the virtual printer 14 corresponding to the first reference coordinate point “a” on the boundary of the color reproduction range of the virtual printer 14 using the dummy RGB color space. Actual mapping is performed in the L*a*b* space.

Since a direction of coordinate conversion (mapping) is decided in a color space matching the human sense of color, i.e., the dummy RGB color space (the color space dependent on a device), the likelihood of discontinuity of tones and an unnatural image is reduced to be extremely small and actual coordinate conversion is performed in the L*a*b* space (the common color space). Thus, highly accurate coordinate conversion (mapping) in terms of color is performed.

FIG. 56 is drawn as if the coordinate conversion (mapping) is performed on a two-dimensional plane for convenience of illustration. However, actually, three-dimensional mapping is performed as described above.

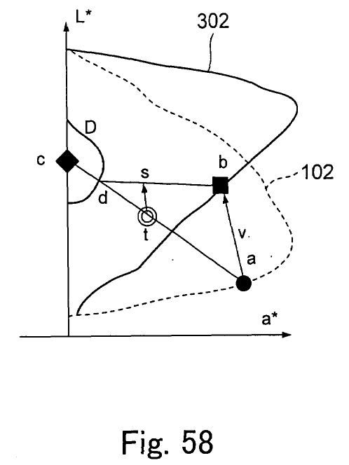

FIG. 58 is a diagram showing a modification of the first example of the coordinate conversion explained with reference to FIGS. 56 and 57.

A range D surrounding the coordinate conversion reference coordinate point “c” is set and a point of intersection “d” of the straight line connecting the coordinate conversion reference coordinate point “c” and the first reference coordinate point “a” and the range D is calculated. In mapping of the first coordinate point “t”, the first coordinate point “t” is mapped to the coordinate point “s” on a straight line connecting the point of intersection “d” and the second reference coordinate point “b”.

In this way, it is possible to set the range D, in which coordinates are not moved. As described above, it is preferable not to move coordinates for the L* axis (the gray axis) in order to keep a gray balance. By setting the range D as shown in FIG. 57, it is possible to arbitrarily set a range in which coordinates are not moved.

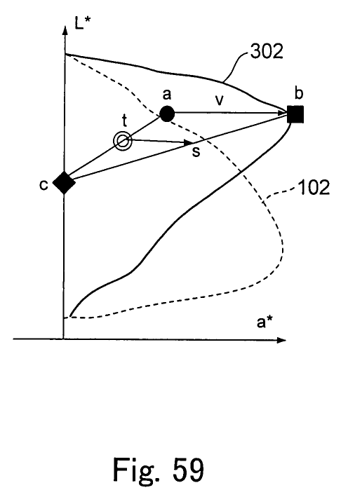

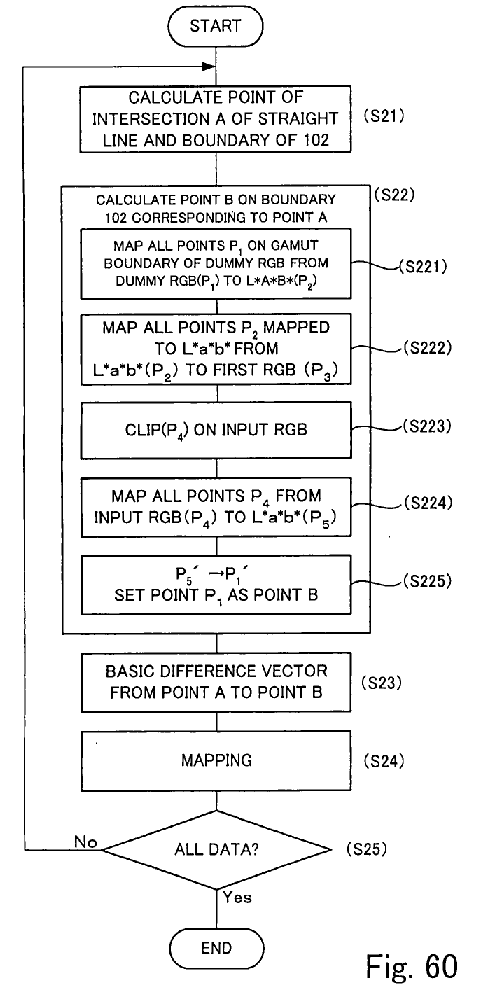

FIG. 59 is an explanatory diagram of a second example of the coordinate conversion in the first step of the flowchart shown in FIG. 52. FIG. 60 is a flowchart of the second example.

As in the first example explained with reference to FIGS. 56 and 57, the coordinate conversion reference coordinate point “c” as a reference of the coordinate conversion on the L* axis (the gray axis) is set.

Assuming a straight line connecting the coordinate conversion reference coordinate point “c” and the first coordinate point “t” as an object of the coordinate conversion, a point of intersection of the straight line and a boundary of the color reproduction range 102 of the printer 11 mapped to the L*a*b* space is calculated (step S21). The point of intersection is referred to as the first reference coordinate point “a”. When adaptive conversion in the second step (step b2) of the flowchart in FIG. 52 is performed, the color reproduction range 102 of the printer 11 mapped to the L*a*b* space indicates a color reproduction range after the adaptive conversion as described above.

Unlike the flowchart shown in FIG. 57, the flowchart shown in FIG. 60 is a flowchart in the case in which the first reference coordinate point “a” calculated in this way is present in the color reproduction range 302 of the virtual printer 14 mapped to the L*a*b* space as shown in FIG. 59. When this condition is satisfied, processing is further performed as described below.

The second reference coordinate point “b” on the boundary of the color reproduction range of the virtual printer 14 corresponding to the first reference coordinate point “a” on the boundary of the color reproduction range of the printer 11 is calculated (step S22). In calculating the second reference coordinate point “b”, as shown in FIG. 59, since the first reference coordinate point “a” is present in the color reproduction range 302 of the virtual printer 14, it is impossible to use the method explained with reference to FIGS. 56 and 57. Even if the first reference coordinate point “a” is mapped to the dummy RGB color space in the same manner as the case in which the first reference coordinate point “a” is present outside the color reproduction range 302 of the virtual printer 14, the first reference coordinate point mapped is located in the color reproduction range of the virtual printer 14 in the dummy RGB color space. Thus, it is impossible to use the method of clip described above. Therefore, the second reference coordinate point “b” is calculated as described below.

First, concerning all points (represented by the point P₁) on the boundary of the color reproduction range (gamut) of the virtual printer 14 in the dummy RGB color space, the points are mapped from the dummy RGB color space to the L*a*b* space (step S221) and all points P₂ mapped to the L*a*b* space are mapped to the input RGB color space (step S222). Subsequently, points deviating from the color reproduction range of the printer 11 on the input RGB color space among points P₃ mapped to the input RGB color space are mapped onto the boundary of the color reproduction range of the printer 11 by, for example, clipping minus values to 0 and clipping values exceeding 255 to 255 for R, G, and B as described above to map the points (step S223).

All points P₄ obtained in this way, which are mapped to the input RGB color space and clipped, are mapped from the input RGB color space to the L*a*b* space (step S224). Among points P₅ mapped to the L*a*b* space in this way, point P₅′ coinciding with the first reference coordinate point “a” or closest thereto, although not coinciding therewith, is found. Among all the points P₁ on the boundary of the color reproduction range of the virtual printer 14 of the dummy RGB color space, a point P₁′ based on which the point P₅′ is obtained is found, and the point P₁′ is set as the second reference coordinate point b (step S225).

It is possible to calculate the second reference coordinate point “b” corresponding to the reference coordinate point “a” shown in FIG. 59 by taking such a procedure.

In the case of the flowchart shown in FIG. 60, all the points P₁ on the boundary of the color reproduction range of the virtual printer 14 in the dummy RGB color space are indiscriminately mapped to the input RGB color space. However, among the coordinate points on the boundary of the color reproduction range 302 of the virtual printer 14 mapped to the L*a*b* space shown in FIG. 51, only coordinate points in a portion sticking out from the color reproduction range 102 of the printer 11 mapped to the L*a*b* space have to be mapped to the input RGB color space. Alternatively, when it is possible to further narrow down a coordinate position of the second reference coordinate point “b” in the portion sticking out from the color reproduction range 102 according to estimation or the like, only coordinate points in a range narrowed down may be mapped to the input RGB color space and clipped.

When the second reference coordinate point “b” is detected in step S22 shown in FIG. 60, as in the case of the flowchart in FIG. 57, as shown in FIG. 59, the basic difference vector “v” from the first reference coordinate point “a” to the second reference coordinate point “b” is calculated (step S23). Moreover, as in the case of the first example in FIGS. 56 and 57, a second coordinate point corresponding to the first coordinate point is calculated (step S24).

Such coordinate conversion is applied to all coordinate points, the first reference coordinate point “a” calculated in step c1 of which is present in the color reproduction range 302 of the virtual printer 14, among the coordinate points in the color reproduction range 102 of the printer 11 mapped to the L*a*b* space (step S25).

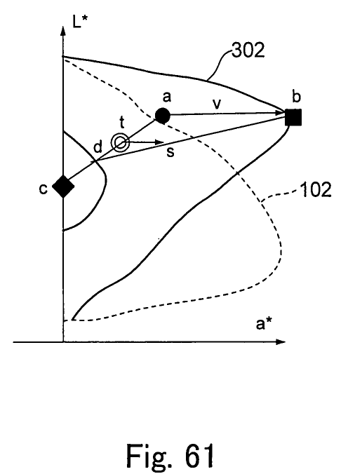

FIG. 61 is a diagram showing a modification of the second example of the coordinate conversion explained with reference to FIGS. 59 and 60.

As in FIG. 58, the range D surrounding the coordinate conversion reference coordinate point “c” is set and the point of intersection “d” of the straight line connecting the coordinate conversion reference coordinate point “c” and the first reference coordinate point “a” and the range D is calculated. The first coordinate point “t” is mapped to the coordinate point “s” on the straight line connecting the point of intersection “d” and the second reference coordinate point “b”. Consequently, it is possible to set the range D, in which coordinates are not moved.

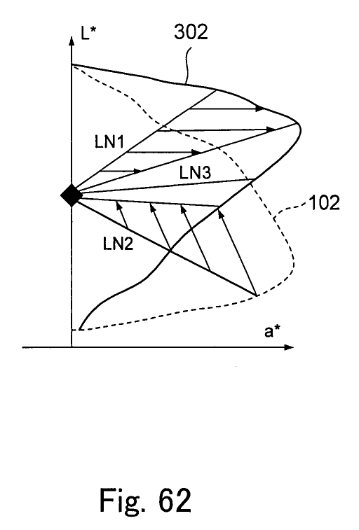

FIG. 62 is a diagram for explaining effects of the mapping performed by combining “compression” explained with reference to FIGS. 56 and 57 and “expansion” explained with reference to FIGS. 59 and 60.

Coordinate points on a line LN1 on which the color reproduction range 302 of the virtual printer 14 on the L*a*b* space is wider than the color reproduction range 102 of the printer 11 on the L*a*b* space are expanded to use the color reproduction range 302 of the virtual printer 14 to the maximum. Coordinate points on a line LN2 on which the color reproduction range 102 of the printer 11 is wider are compressed to a level for using the color reproduction range 302 of the virtual printer 14 to the maximum. A direction of the expansion and the compression is calculated using the RGB space dependent on a device. Thus, even if the mapping itself is performed on the L*a*b* space, occurrence of discontinuity of tones and unnatural images is prevented. Since the mapping itself is performed in the L*a*b* space, highly accurate mapping is performed. Since coordinate points on a line LN3 on which the width of the color reproduction range 102 of the printer 11 and the width of the color reproduction range 302 of the virtual printer 14 coincide with each other do not move, colors are kept.

The mapping performed here is drawn as if the mapping is performed on the L*-a* plane for convenience of illustration in FIG. 62. However, the mapping is performed three-dimensionally as described above.

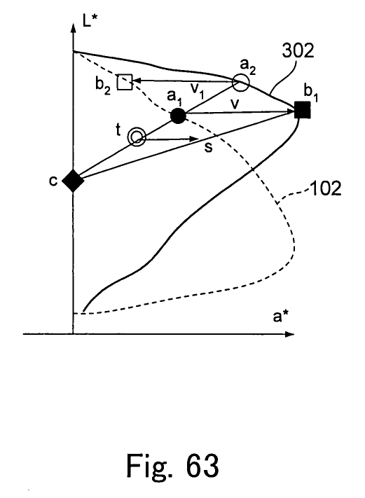

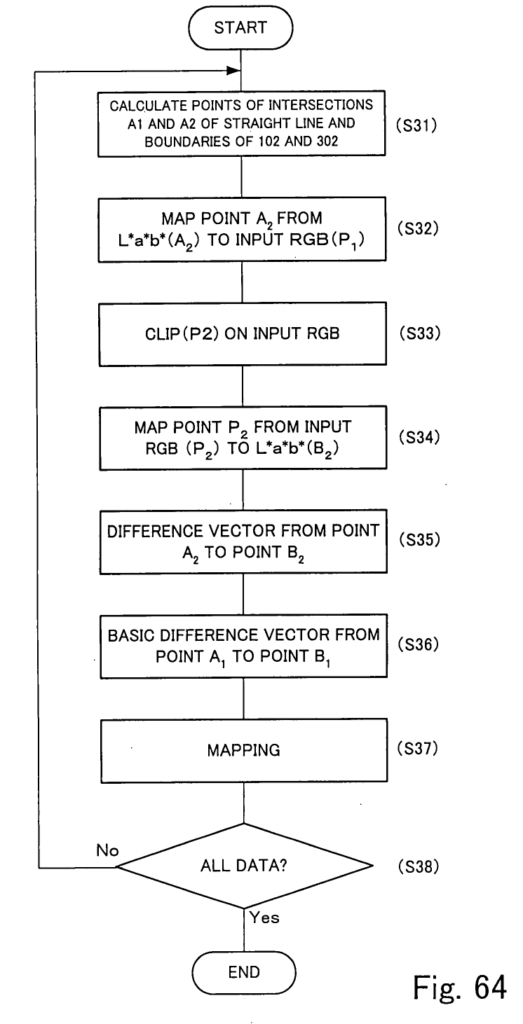

FIG. 63 is an explanatory diagram of a third example of the coordinate conversion in the first step of the flowchart shown in FIG. 52. FIG. 64 is a flowchart of the third example. The third example explained here is, as in the case of the second example explained with reference to FIGS. 59 and 60, an example of the case in which the first reference coordinate point “a1” calculated in step S31 is present in the color reproduction range 302 of the virtual printer 14 mapped to the L*a*b* space.

As in the first example and the second example, the coordinate conversion reference coordinate point “c” as a reference of the coordinate conversion is set on the L* axis (the gray axis). Assuming a straight line connecting the coordinate conversion reference coordinate point “c” and the first coordinate point “t” as an object of the coordinate conversion, a point of intersection of the straight line and a boundary of the color reproduction range 102 of the printer 11 mapped to the L*a*b* space is calculated. The point of intersection is set as a first reference coordinate point a1. A point of intersection of the straight line and a boundary of the color reproduction range 302 of the virtual printer 14 mapped to the L*a*b* space is further calculated and the point of intersection is set as a third reference coordinate point a2 (step S31). When adaptive conversion in the second step (step b21) of the flowchart in FIG. 52 is performed, the color reproduction range 102 of the printer 11 mapped to the L*a*b* space indicates a color reproduction range after the adaptive conversion as in the case of the first example and the second example.

Subsequently, the third reference coordinate point a2 calculated as described above is mapped from the L*a*b* space to the input RGB color space dependent on the printer 11 (step S32). The point P₁ mapped to the input RGB color space is clipped in the input RGB color space to be mapped onto the boundary of the color reproduction range of the printer 11 (step S33). The point P₂ obtained by the mapping is mapped to the L*a*b* space (step S34). A point on the boundary of the color reproduction range 102 of the printer 11 in the L*a*b* space obtained in this way is referred to as a fourth reference coordinate point b2.

A difference vector v1 from the third reference coordinate point a2 to the fourth reference coordinate point b2 is calculated (step S35). Assuming a straight line passing through the first reference coordinate point a1 and parallel to the difference vector v1, an intersection of the straight line and the boundary of the color reproduction range 302 of the virtual printer 14 on the L*a*b* space is set as a second reference coordinate point b1. The basic difference vector “v” from the first reference coordinate point a1 to the second reference coordinate point b1 is calculated (step S36). Thereafter, as in the first example and the second example, the first coordinate point “t” is moved in parallel to the basic difference vector “v” and mapped to a coordinate point (the second coordinate point “s”) where the first coordinate point “t” meets the straight line connecting the coordinate conversion reference coordinate point “c” and the second reference coordinate point b1 (step S37).

Such coordinate conversion is applied to all the coordinate points, for which the first reference coordinate point a1 located in the color reproduction range 302 of the virtual printer 14 on the L*a*b* space is calculated in step d1, among the coordinate points in the color reproduction range of the printer 11 on the L*a*b* space (step S38).

In the third example shown in FIGS. 63 and 64, when the color reproduction range 102 of the printer 11 on the L*a*b* space and the color reproduction range 302 of the virtual printer 14 deviate by a great degree, i.e., when the difference vector v1 and the basic difference vector “v” are apart by a large distance, an error occurs. However, when the two vectors v1 and “v” are close and an error between the two vectors v1 and “v” is negligible, it is possible to adopt the third example. It is possible to perform a high-speed arithmetic operation compared with the second example explained with reference to FIGS. 59 and 60.

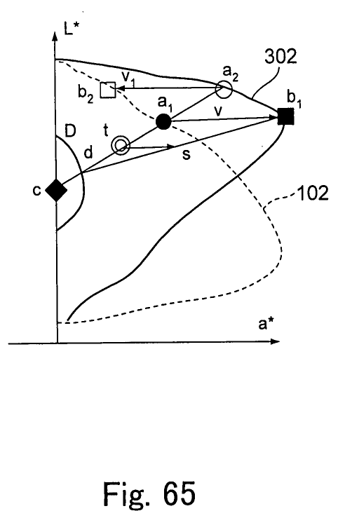

FIG. 65 is a diagram showing a modification of the third example of the coordinate conversion explained with reference to FIGS. 63 and 64.

As in FIGS. 58 and 61, the range D surrounding the coordinate conversion reference coordinate point “c” is set, the point of intersection “d” of the straight line connecting the coordinate conversion reference coordinate point “c” and the first reference coordinate point a1 and the boundary of the range D is calculated, and the first coordinate point “t” is mapped onto the straight line connecting the point of intersection “d” and the second reference coordinate point b1.

In this way, it is possible to set the range D in which coordinate movement is not performed.

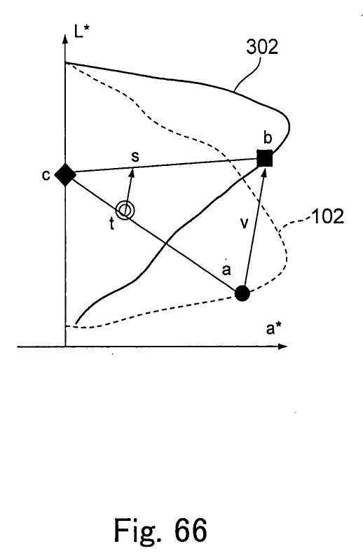

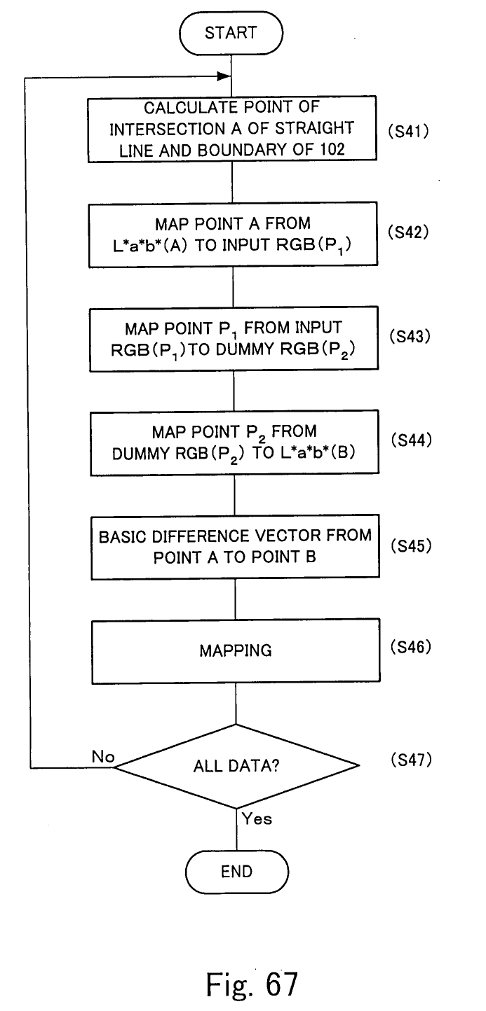

FIG. 66 is an explanatory diagram of a fourth example of the coordinate conversion in the first step of the flowchart shown in FIG. 52. FIG. 67 is a flowchart of the fourth example.

This fourth example is a method that can be applied without considering whether the first reference coordinate point “a” calculated in step c1 is present in the color reproduction range 302 of the virtual printer 14 mapped to the L*a*b* space or deviates from the color reproduction range 302.

As in the first to the third examples, the coordinate conversion reference coordinate point “c” is set on the L* axis (the gray axis) and, assuming a straight line connecting the coordinate conversion reference coordinate point “c” and the first coordinate point “t” as an object of coordinate conversion, a point of intersection of the straight line and the boundary of the color reproduction range 102 of the printer 11 on the L*a*b* space is calculated, and the point of intersection is set as the first reference coordinate point “a” (step S41).

Subsequently, the first reference coordinate point “a” is mapped to the input RGB color space, which is a color space dependent on the printer 11 (step S42).

A coordinate point P₂ on the dummy RGB color space, which is a color space dependent on the virtual printer 14, having a coordinate value corresponding to a coordinate value of the point P₁ on the input RGB color space mapped to the input RGB color space in this way, typically, a coordinate value identical with the coordinate value of the point P₁ is calculated (step S43). As a specific example, when a coordinate value of the point P₁ obtained by mapping the first reference coordinate point “a” shown in FIG. 66 to the input RGB color space is (R, G, B)=(0, 255, 0), a point on the dummy RGB color space having the identical coordinate value (R, G, B)=(0, 255, 0) is set as the point P₂.

The point P₂ on the dummy RGB color space is mapped from the dummy RGB color space to the L*a*b* space and the mapped point is set as the second reference coordinate point “b” (step S44).

The first reference coordinate point “a” is a point on the boundary of the color reproduction range 102 of the printer 11 on the L*a*b* space. Thus, even if the first reference coordinate point “a” is mapped to the input RGB color space, the first reference coordinate point “a” is a point on the boundary of the color reproduction range of the printer 11 in the input RGB color space (e.g., (R, G, B)=(0, 255, 0) described above).

When the point is directly set as a point on the dummy RGB color space, the point is a point on the boundary of the color reproduction range of the virtual printer 14 on the dummy RGB color space. The second reference coordinate point “b” calculated by mapping the point to the L*a*b* space is also a point on the boundary of the color reproduction range 302 of the virtual printer 14 on the L*a*b* space.

The basic difference vector “v” from the first reference coordinate point “a” to the second reference coordinate point “b” thus obtained is calculated (step S45). The second coordinate point “s”, which is a point of intersection of a straight line passing through the first coordinate point “t” and drawn in parallel to the basic difference vector “v” and a straight line connecting the coordinate conversion reference coordinate point “c” and the second reference coordinate point “b”, is calculated (step S46).

The coordinate conversion is applied to the entire color reproduction range 102 of the printer 11 on the L*a*b* space.

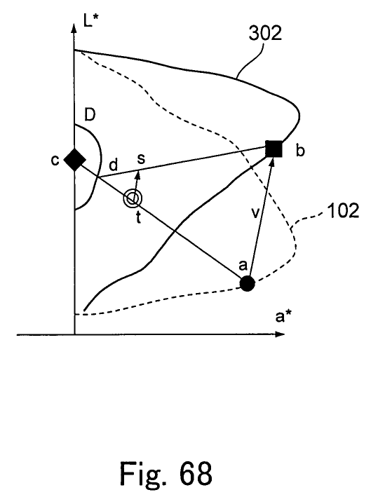

FIG. 68 is a diagram showing a modification of the fourth example of the coordinate conversion explained with reference to FIGS. 66 and 67.

As in the examples in FIGS. 58, 61, and 65, the range D is set around the coordinate conversion reference coordinate point “c” and mapping is not performed in the range D. A method of preventing mapping in the range D is the same as that in the examples in FIGS. 58, 61, and 65. Thus, an explanation of the method is omitted.

Referring back to FIG. 52, the third coordinate converting step (step c3) will be explained.

In the third coordinate converting step (step c3), coordinate points in the color reproduction range 302 of the virtual printer 14 after the coordinate conversion (mapping) from the color reproduction range 102 of the printer 11 to the color reproduction range 302 of the virtual printer 14 is performed on the L*a*b* space are mapped to the dummy RGB color space on the basis of color reproducibility (a proofer profile) of the virtual printer 14.

In the second link-profile creating step (step (C)) of the color conversion definition creating method shown in FIG. 5, a second link profile for converting coordinate points in the color reproduction range of the printer 11 in the input RGB color space, which is a color space dependent on the printer 11, into coordinate points in the color reproduction range of the virtual printer 14 (a color reproduction range sufficiently coinciding with the color reproduction range of the printing system 12) in the dummy RGB color space, which is a color space dependent on the virtual printer 14 having a color reproduction range sufficiently coinciding with the color reproduction range of the printing system 12, is calculated as described above.

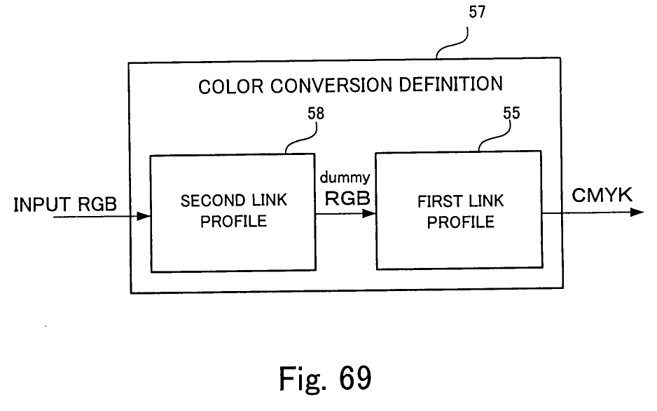

FIG. 69 is a conceptual diagram showing a color conversion definition including the first link profile and the second link profile.

The first link profile (the link profile 55 shown in FIG. 17) calculated in the first link-profile creating step in step (B) in FIG. 5 and the second link profile calculated in the second link-profile creating step in step (C) in FIG. 5 are combined to create a color conversion definition 57 for converting RGB data for a printer (data representing coordinate points in the input RGB color space) into CMYK data for printing (data representing coordinate points in the CMYK color space adapted to the printing system 12 (see FIG. 2)).

Thereafter, it is desirable to smooth zigzag of CMYK values due to zigzag of B2A1 by smoothing CMYK using the method of sectional polynomial approximation disclosed in Japanese Patent Application Laid-Open No. 2004-266590.

As described above, the color conversion definition 57 created in this way is set in the color converting apparatus 10 shown in FIG. 2. The color conversion definition 57 set in the color converting apparatus 10 is used in converting RGB data for the printer 11 representing an actual image into CMYK data for printing in the color converting apparatus 10.

The CMYK data generated by the conversion using the color conversion definition 57 is CMYK data with which it is possible to obtain the print image 12a that satisfies the K plate constraint and the limitation on a total amount of ink of the printing system 12 (i.e., excellent in printability), “satisfactorily” absorbs a difference between the color reproduction range of the printer 11 and the color reproduction range of the printing system 12, and reproduces preferable colors approximate to colors of the print image 11a print-outputted by the printer 11 on the basis of the RGB data for the printer 11 before the conversion.

In the embodiment, the printer 11 shown in FIG. 2 is adopted as the first device according to the present invention. However, the first device according to the invention is not limited to an output device such as the printer 11 and may be, for example, an input device such as a color scanner that scans an image and outputs image data of R, G, and B. It is also possible to apply the invention in creating a color conversion definition for converting RGB data obtained by the input device into CMYK data having preferable colors in a relation with the colors from which the RGB data is obtained and excellent in printability.

In the embodiment, the virtual printer 14 shown in FIG. 2 is adopted as the second device according to the invention. However, as the second device according to the invention, a device of any type may be assumed as long as the device is assumed to have a color reproduction range sufficiently coinciding with the color reproduction range of the printing system 12.

What is claimed is:

1. A color conversion definition creating method of creating a color conversion definition for converting a coordinate point in a color reproduction range of a first device, which mediates an image and image data, in a first RGB color space dependent on the first device into a coordinate point in a color reproduction range for printing in a CMYK color space for printing, the color conversion definition creating method comprising:
a profile creating step of creating a virtual profile between a second RGB color space and a predetermined common color space, the second RGB color having a color reproduction range obtained by tracing the color reproduction range for printing and depending on a virtual second device which mediates an image and image data;
a first link-profile creating step of creating a first link profile that converts a coordinate point in a color reproduction range of the second device in the second RGB color space into a coordinate point in the color reproduction range for printing in the CMYK color space; and
a second link-profile creating step of creating a second link profile that converts a coordinate point in the color reproduction range of the first device in the first RGB color space into a coordinate point in the color reproduction range of the second device in the second RGB color space using a device profile of the first device and the virtual profile created in the profile creating step, wherein
the profile creating step includes:
a color-reproduction-range calculating step of calculating a printable color reproduction range in the common color space, which is obtained by mapping a color reproduction range adjusted for printing in the CMYK color space for printing to the common color space, using an adaptive conversion profile that converts a coordinate point in the CMYK color space for printing into a coordinate point in the common color space and an inverse conversion profile that converts a coordinate point in the common color space into a coordinate point in the color reproduction range adjusted for printing in the CMYK color space for printing; and
a virtual-profile creating step of creating a virtual profile by linking the printable color reproduction range calculated in the color-reproduction-range calculating step and the second RGB color space.

2. The color conversion definition creating method according to claim 1, wherein the color-reproduction-range calculating step includes:
an inverse conversion step of converting a coordinate point on the common color space into a coordinate point in the color reproduction range adjusted for printing in the CMYK color space using the inverse conversion profile; and
an adaptive conversion step of converting the coordinate point in the color reproduction range adjusted to the printing in the CMYK color space obtained in the inverse conversion step into a coordinate point on the common color space using the adaptive conversion profile.

3. The color conversion definition creating method according to claim 1, wherein the color-reproduction-range calculating step is a step of calculating the printable color reproduction range using an A2B1 tag of an ICC profile as the adaptive conversion profile and using any one of a B2A0 tag, a B2A1 tag, and B2A2 tag of the ICC profile as the inverse conversion profile.

4. The color conversion definition creating method according to claim 1, wherein the virtual-profile creating step includes:
a vertex-and-ridge-line detecting step of detecting respective vertices of W, R, G, B, C, M, Y, and K of the printable color reproduction range in the common color space calculated in the color-reproduction-range calculating step and twelve ridge lines connecting R and M, M and B, B and C, C and G, G and Y, Y and R, W and C, W and M, W and Y, K and R, K and G, and K and B and associating these vertices and the ridge lines with vertices and ridge lines corresponding thereto, respectively, in the RGB color space;
a ridge-line-profile creating step of creating a ridge line profile concerning respective ridge lines associating a coordinate point in the RGB color space and a coordinate point in the common color space such that, when plural points are set at equal intervals on the respective ridge lines on the RGB color space and the plural points are mapped onto the common color space, the plural points mapped onto the common color space are arranged at equal intervals on the respective ridge lines on the common color space;
a gray-axis-profile creating step of creating a gray axis profile concerning a gray axis associating a coordinate point in the RGB color space and a coordinate point in the common color space such that, when plural points are set at equal intervals on the gray axis connecting the vertex of W and the vertex of K on the RGB space and the plural points are mapped onto the common color space, the plural points mapped onto the common color space are arranged at equal intervals on the gray axis connecting the vertex of W and the vertex of K on the common color space; and
an interpolation operation step of creating a virtual profile by associating a coordinate point in the RGB space and a coordinate point in the common color space over the entire RGB color space according to an interpolation operation with the ridge line profile created in the ridge-line-profile creating step and the gray axis profile created in the gray-axis-profile creating step set as boundary conditions.

5. The color conversion definition creating method according to claim 4, wherein, in the vertex-and-ridge-line detecting step, a locus of a color of a maximum chroma in a two-dimensional color reproduction range obtained by projecting the printable color reproduction range on one or more planes is detected and ridge lines connecting R, M, B, C, G, Y, and R in order are detected on the basis of the locus.

6. The color conversion definition creating method according to claim 4, wherein, in the vertex-and-ridge-line detecting step, by detecting angles in respective hue angle ranges set for R, M, B, C, G, and Y, respectively, of the ridge lines connecting R, M, B, C, G, Y, and R in order detected on the printable color reproduction range, the angles in the respective hue ranges are associated with the respective vertices of R, M, B, C, G, and Y.

7. The color conversion definition creating method according to claim 4, wherein, in the vertex-and-ridge-line detecting step, respective outermost edges connecting respective vertices of R, G, and B and a vertex of K of respective two-dimensional color reproduction ranges obtained by projecting the printable color reproduction range on respective planes including the gray axis and the respective vertices of R, G, and B are set as respective ridge lines connecting the respective vertices of R, G, and G and the vertex of K in the printable color reproduction range, and respective outermost edges connecting a vertex of W and respective vertices of C, M, and Y of respective two-dimensional color reproduction ranges obtained by projecting the printable color reproduction range on the respective planes including the gray axis and the respective vertices of C, M, and Y are set as respective ridge lines connecting the vertex of W and the respective vertices of C, M, and Y in the printable color reproduction range.

8. The color conversion definition creating method according to claim 4, wherein, in the vertex-and-ridge-line detecting step, noise removal processing is applied to a ridge line once detected to detect a ridge line with noise reduced.

9. The color conversion definition creating method according to claim 8, wherein the vertex-and-ridge-line detecting step is a step of calculating a chroma ratio of each point on a ridge line once detected to a point adjacent thereto and, when the chroma ratio is equal to or lower than a threshold, removing a point where the chroma is low as noise.

10. The color conversion definition creating method according to claim 8, wherein the vertex-and-ridge-line detecting step is a step of calculating a difference vector between each point on a ridge line detected once and a point adjacent thereto and, when signs of components in a lightness direction of the difference vector continuously take maximum and minimum, these two points of extreme values are removed as noise.

11. A profile creating method of creating a virtual profile between an RGB color space dependent on a virtual device, which mediates an image and image data, and a predetermined common color space, the profile creating method comprising:
a color-reproduction-range calculating step of calculating a printable color preproduction range in the common color space, which is obtained by mapping a color reproduction range adjusted for printing in a CMYK color space for printing to the common color space, using an adaptive conversion profile that converts a coordinate point in the CMYK color space for printing into a coordinate point in the common color space and an inverse conversion profile that converts the coordinate point in the common color space into a coordinate point in the color reproduction range adjusted for printing; and
a virtual-profile creating step of creating a virtual profile by linking the printable color reproduction range calculated in the color-reproduction-range calculating step and the RGB color space.

12. A color conversion definition creating apparatus that creates a color conversion definition for converting a coordinate point in a color reproduction range of a first device, which mediates an image and image data, in a first RGB color space dependent on the first device into a coordinate point in a color reproduction range for printing in a CMYK color space for printing, the color conversion definition creating apparatus comprising:
a profile creating section that creates a virtual profile between a second RGB color space and a predetermined common color space, the second RGB color space having a color reproduction range obtained by tracing the color reproduction range for printing and depending on a virtual second device which mediates an image and image data;
a first link-profile creating section that creates a first link profile that converts a coordinate point in a color reproduction range of the second device in the second RGB color space into a coordinate point in the color reproduction range for printing in the CMYK color space; and
a second link-profile creating section that creates a second link profile that converts a coordinate point in the color reproduction range of the first device in the first RGB color space into a coordinate point in the color reproduction range of the second device in the second RGB color space using a device profile of the first device and the virtual profile created by the profile creating section, wherein
the profile creating section includes:
a color-reproduction-range calculating section that calculates a printable color reproduction range in a common color space, which is obtained by mapping a color reproduction range adjusted for printing in the CMYK color space for printing to the common color space, using an adaptive conversion profile that converts a coordinate point in the CMYK color space for printing into a coordinate point in the common color space and an inverse conversion profile that converts a coordinate point in the common color space into a coordinate point in the color reproduction range adjusted for printing in the CMYK color space for printing; and
a virtual-profile creating section that creates a virtual device profile by linking the printable color reproduction range calculated by the color-reproduction-range calculating section and the second RGB color space.

13. A profile creating apparatus that creates a virtual profile between an RGB color space dependent on a virtual device, which mediates an image and image data, and a predetermined common color space, the profile creating apparatus comprising:
a color-reproduction-range calculating section that calculates a printable color preproduction range in the common color space, which is obtained by mapping a color reproduction range adjusted for printing in a CMYK color space for printing to the common color space, using an adaptive conversion profile that converts a coordinate point in the CMYK color space for printing into a coordinate point in the common color space and an inverse conversion profile that converts a coordinate point in the common color space into a coordinate point in the color reproduction range adjusted for printing; and
a virtual-profile creating section that creates a virtual profile by linking the printable color reproduction range calculated by the color-reproduction-range calculating section and the RGB color space.

14. A storage medium having stored therein a color conversion definition creating program that is executed in an information processing apparatus, which executes a program, and causes the information processing apparatus to operate as a color conversion definition creating apparatus that creates a color conversion definition for converting a coordinate point in a color reproduction range of a first device, which mediates an image and image data, in a first RGB color space dependent on the first device into a coordinate point in a color reproduction range for printing in a CMYK color space for printing, the color conversion definition creating program causing the information processing apparatus to operate as a color conversion definition creating apparatus comprising:
a profile creating section that creates a virtual profile between a second RGB color space and a predetermined common color space, the second RGB color space having a color reproduction range obtained by tracing the color reproduction range for printing and depending on a virtual second device which mediates an image and image data;
a first link-profile creating section that creates a first link profile that converts a coordinate point in a color reproduction range of the second device in the second RGB color space into a coordinate point in the color reproduction range for printing in the CMYK color space; and
a second link-profile creating section that creates a second link profile that converts a coordinate point in the color reproduction range of the first device in the first RGB color space into a coordinate point in the color reproduction range of the second device in the second RGB color space using a device profile of the first device and the virtual profile created by the profile creating section, wherein
the profile creating section includes:
a color-reproduction-range calculating section that calculates a printable color reproduction range in a common color space, which is obtained by mapping a color reproduction range adjusted for printing in the CMYK color space for printing to the common color space, using an adaptive conversion profile that converts a coordinate point in the CMYK color space for printing into a coordinate point in the common color space and an inverse conversion profile that converts a coordinate point in the common color space into a coordinate point in the color reproduction range adjusted for printing in the CMYK color space for printing; and
a virtual-profile creating section that creates a virtual device profile by linking the printable color reproduction range calculated by the color-reproduction-range calculating section and the second RGB color space.

15. A storage medium having stored therein a profile creating program that is executed in an information processing apparatus, which executes a program, and causes the information processing apparatus to operate as a profile creating apparatus that creates a virtual profile between an RGB color space dependent on a virtual device, which mediates an image and image data, and a predetermined common color space, the profile creating program causing the information processing apparatus to operate as a profile creating apparatus comprising:
a color-reproduction-range calculating section that calculates a printable color preproduction range in the common color space, which is obtained by mapping a color reproduction range adjusted for printing in a CMYK color space for printing to the common color space, using an adaptive conversion profile that converts a coordinate point in the CMYK color space for printing into a coordinate point in the common color space and an inverse conversion profile that converts a coordinate point in the common color space into a coordinate point in the color reproduction range adjusted for printing; and
a virtual-profile creating section that creates a virtual profile by linking the printable color reproduction range calculated by the color-reproduction-range calculating section and the RGB color space.
